(19) United States
(12) Patent Application Publication
(10) Pub. No.: US 2011/0063812 A1
(43) Pub. Date: Mar. 17, 2011

(54) ELECTRONIC DEVICE, METHOD OF MANUFACTURING ELECTRONIC DEVICE, AND ELECTRONIC EQUIPMENT

(75) Inventors: Teru NAKANISHI, Kawasaki (JP); Nobuyuki Hayashi, Kawasaki (JP); Masaru Morita, Kawasaki (JP); Yasuhiro Yoneda, Kawasaki (JP)

(73) Assignee: FUJITSU LIMITED, Kawasaki (JP)

(21) Appl. No.: 12/853,647

(22) Filed: Aug. 10, 2010

(30) Foreign Application Priority Data
Sep. 11, 2009 (JP) 2009-210022
Mar. 18, 2010 (JP) 2010-061787

(51) Int. Cl. H05K 7/02; H05K 3/30

(52) U.S. Cl. 361/783; 29/832

(57) ABSTRACT

An electronic device includes a circuit board having a first electrode formed on a main surface thereof, a semiconductor device disposed toward the main surface of the circuit board, the semiconductor device having a second electrode formed on a surface thereof opposed to the main surface, and a connection member electrically connecting between the first and second electrodes. The connection member includes a hollow cylindrical member and a conductive member disposed within the hollow cylindrical member.

### CROSS-REFERENCE TO RELATED APPLICATIONS

This application is based upon and claims the benefit of priority of the prior Japanese Patent Applications No. 2009-210022 filed on Sep. 11, 2009, and No. 2010-061787 filed on Mar. 18, 2010, the entire contents of which are incorporated herein by reference.

### FIELD

The embodiments discussed herein are related to an electronic device including a semiconductor device and a circuit board, a method of manufacturing the electronic device, and electronic equipment including the electronic device.

### BACKGROUND

One possible form of connection between a semiconductor device and a circuit board is flip-chip connection. Conventionally, solder bumps have been widely used for the flip-chip connection. In this case, the solder bumps are melted in a state arranged between electrodes of a semiconductor device and those of a circuit board, and then are solidified, for electrically connecting the semiconductor device and the circuit board by soldering. Further, there has been proposed a method of evaluating the connection reliability of such solder connection portions by a heat cycle test and a bending test.

As a method of connecting the semiconductor device and the circuit board, there have been known a method for connecting them using gold (Au) bumps and solder, a method for extending solder joints in a direction separating the semiconductor device and the circuit board from each other, etc.

Further, there have also conventionally been known a technique for connecting between different members using a solder joint material having a solder material impregnated in a surface or pores of a foam metal material, and the like.

Japanese Patent No. 3868766

Japanese Laid-Open Patent Publication No. 11-111776

Japanese Laid-Open Patent Publication No. 2004-298962

“High Acceleration Test of Lead-free Solder” 23rd Spring Lecture Meeting of Japan Institute of Electronics Packaging, March, 2009, 11C-08

In the connection between the semiconductor device and the circuit board using bumps, there is a case that stress is generated in the connection portions between the semiconductor device and the circuit board due to thermal expansion and contraction of the semiconductor device and the circuit board connected to each other, and the repetition of generation of stress causes metal fatigue, which sometimes results in breakage of the connection portions. Further, when the semiconductor device and the circuit board are connected using bumps, as the semiconductor device and the circuit board each have a smaller inter-electrode pitch, there is a higher possibility that adjacent ones of the bumps are merged, thereby causing a short circuit (bridge).

### SUMMARY

According to one aspect of the invention, there is provided an electronic device including a circuit board having a first electrode formed on a main surface thereof, a semiconductor device disposed toward the main surface of the circuit board, the semiconductor device having a second electrode formed on a surface thereof opposed to the main surface, and a connection member including a hollow cylindrical member and a conductive member disposed within the hollow cylindrical member, and electrically connecting between the first electrode and the second electrode.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWING(S)

FIG. 1 is a diagram illustrating an example of an electronic device;

FIG. 2 is a diagram illustrating an example of a connection member;

FIGS. 3A and 3B are diagrams illustrating an example of a method of forming an electronic device;

FIGS. 4A and 4B are diagrams illustrating examples of respective states of the electronic device during downtime and during operation;

FIGS. 5A and 5B are diagrams illustrating another example of the method of forming the electronic device;

FIGS. 6A and 6B are diagrams illustrating an example of a circuit board;

FIGS. 7A and 7B are diagrams illustrating an example of a semiconductor package;

FIGS. 8A to 8D are diagrams illustrating an example of a process step of forming connection members according to a first embodiment;

FIGS. 9A to 9C are diagrams illustrating an example of a process step of connecting the connection members according to the first embodiment;

FIGS. 10A and 10B are diagrams illustrating an example of a process step of mounting a semiconductor package according to the first embodiment;

FIGS. 11A to 11E are diagrams illustrating an example of a process step of forming connection members according to a second embodiment;

FIGS. 12A to 12C are diagrams illustrating an example of a process step of connecting the connection members according to the second embodiment;

FIGS. 13A and 13B are diagrams illustrating an example of a process step of mounting a semiconductor package according to the second embodiment;

FIGS. 14A and 14B are explanatory diagrams of a connection member according to a third embodiment;

FIGS. 15A and 15B are diagrams illustrating an example of a process step of mounting a semiconductor package according to the third embodiment;

FIGS. 16A and 16B are explanatory diagrams of a connection member according to a fourth embodiment;

FIGS. 17A and 17B are diagrams illustrating an example of a process step of mounting a semiconductor package according to the fourth embodiment;

FIGS. 18A to 18D are diagrams illustrating an example of a process step of forming connection members according to a fifth embodiment;

FIGS. 19A and 19B are diagrams illustrating an example of a process step of mounting a semiconductor package according to the fifth embodiment;

FIGS. 20A to 20F are diagrams illustrating an example of a process step of forming connection members according to a sixth embodiment;

FIGS. 21A and 21B are diagrams illustrating an example of a process step of mounting a semiconductor package according to the sixth embodiment;

FIG. 22 is a diagram illustrating an example of an electronic device including a cooling structure;

FIG. 23 is a diagram illustrating another example of an electronic device including a cooling structure;

FIG. 24 is a schematic diagram illustrating an example of electronic equipment;

FIGS. 25A and 25B are diagrams illustrating another example of the semiconductor package (another example 1);

FIGS. 26A and 26B are diagrams illustrating still another example of the semiconductor package (another example 2);

FIGS. 27A and 27B are diagrams illustrating still another example of the semiconductor package (another example 3);

FIGS. 28A and 28B are diagrams illustrating an example of a sample;

FIGS. 29A and 29B are diagrams illustrating an example of a method of forming the sample;

FIGS. 30A and 30B are diagrams illustrating an example of the construction of a bending device for use in a bending test; and

FIGS. 31A and 31B are explanatory diagrams of an example of the bending test.

### DESCRIPTION OF EMBODIMENT(S)

Embodiments of the present invention will be explained below with reference to the accompanying drawings, wherein like reference numerals refer to like elements throughout.

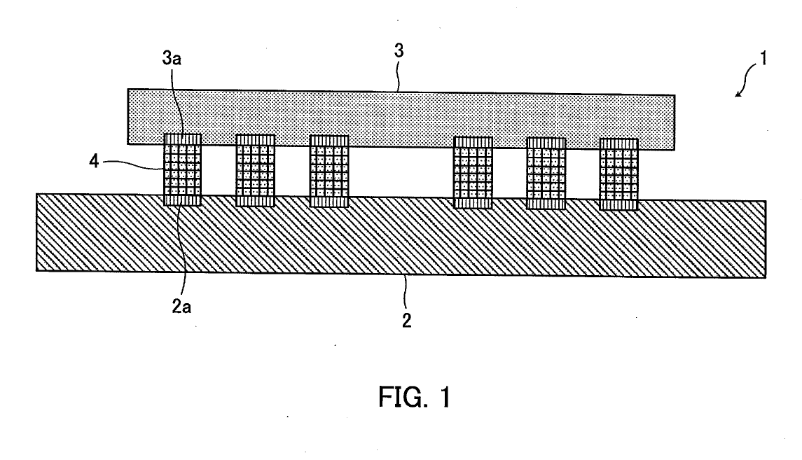

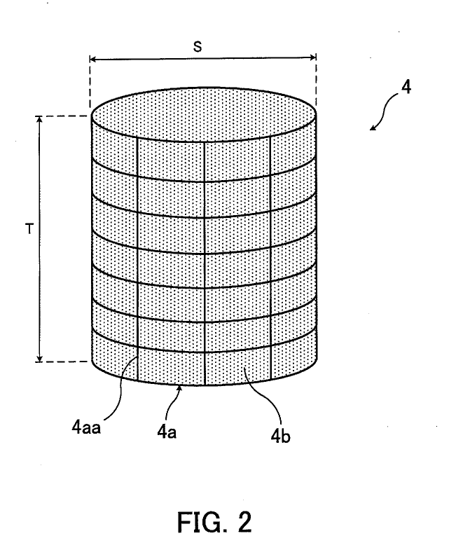

FIG. 1 illustrates an example of an electronic device, and FIG. 2 illustrates an example of a connection member. The electronic device 1 illustrated in FIG. 1 includes a circuit board 2, and a semiconductor device 3. The circuit board 2 and the semiconductor device 3 are connected to each other using a plurality of connection members 4.

The circuit board 2 has a plurality of electrodes 2a formed on a main surface thereof. Although not illustrated here, the electrodes 2a are electrically connected to a conductive trace pattern (e.g. traces and vias) provided on the circuit board 2.

The semiconductor device 3 is disposed over the circuit board 2, and has a plurality of electrodes 3a provided on a surface opposed to the surface of the circuit board 2 on which the electrodes 2a are formed. Although not illustrated here, each electrode 3a is electrically connected to a circuit element (a transistor, a resistance, a capacitor, or the like) provided on the semiconductor device 3.

A semiconductor package including e.g. a semiconductor chip can be used for the semiconductor device 3. As the semiconductor package, it is possible to use a semiconductor package made by electrically connecting (mounting) a semiconductor chip to a circuit board, such as an interposer, by flip-chip connection, wire bonding or the like, and sealing the semiconductor chip and the circuit board with a sealing resin into a package.

The semiconductor device 3 can be applied not only to the semiconductor package formed as described above but also to a semiconductor chip. More specifically, an interposer and a semiconductor chip, for example, are used for the circuit board 2 appearing in FIG. 1 and the semiconductor device 3 appearing in the same, respectively, and the interposer and the semiconductor chip are connected to each other using the connection members 4. In this case, it is possible to obtain an electronic device 1 (semiconductor device) which includes the interposer and the semiconductor chip connected to each other using the connection members 4.

The electrodes 2a of the above-described circuit board 2 and the electrodes 3a of the above-described semiconductor device 3 are formed in advance at respective locations corresponding to each other. The electrodes 2a of the circuit board 2 and the electrodes 3a of the semiconductor device 3 are electrically connected to each other using the connection members 4.

Referring to FIG. 2, each connection member 4 includes a hollow cylindrical member 4a and a conductive member 4b disposed within the hollow cylindrical member 4a.

For the hollow cylindrical member 4a of the connection member 4, it is possible to use e.g. thin wires 4aa formed into a mesh-like shape, as illustrated in FIG. 2. Each thin wire 4aa may be made of a metal or a resin. For the hollow cylindrical member 4a, it is also possible to use a metal or resin thin wire formed into a coil, a metal or resin plate or sheet formed into a hollow cylindrical shape, or the like.

For the hollow cylindrical member 4a, it is possible to use a metal containing one or not less than two of copper (Cu), a Cu alloy, nickel (Ni), an iron-nickel (Fe—Ni) alloy, palladium (Pd), a Pd alloy, platinum (Pt), and a Pt alloy. Further, e.g. an aromatic polyamide resin as well can be used for the hollow cylindrical member 4a.

To select a material of the hollow cylindrical member 4a, a material of the conductive member 4b disposed within the hollow cylindrical member 4a is taken into account.

More specifically, as described hereinafter, when mounting the semiconductor device 3 on the circuit board 2, the conductive member 4b disposed within the hollow cylindrical member 4a is melted by being heated and is then solidified, whereby the circuit board 2 and the semiconductor device 3 are connected to each other. As the material of the hollow cylindrical member 4a, it is desirable to use a heat-resistant material which is difficult to be melted or deteriorated when the conductive member 4b is heated to be melted, as described above.

Further, as the material of the hollow cylindrical member 4a, it is desirable to use such a material that the conductive member 4b melted by heating can wet, so as to suppress connection failure between the circuit board 2 and semiconductor device 3. Alternatively, as the material of the hollow cylindrical member 4a, it is desirable to use a material subjected to surface treatment so as to be wetted by the molten conductive member 4b.

Although in the example illustrated in FIG. 2, the hollow cylindrical member 4a has a circular shape in cross section, this is not limitative, but it is also possible to use a hollow cylindrical member having an elliptic shape or a polygonal shape in cross section, for the hollow cylindrical member 4a. Further, the hollow cylindrical member 4a is not necessarily required to have a closed cross-sectional shape, but a partially broken shape in cross section can be used as the hollow cylindrical member 4a.

For the conductive member 4b disposed within the hollow cylindrical member 4a configured as above, there is used a material which has a predetermined conductivity, wets the hollow cylindrical member 4a, and further has a melting point lower than the heat-resistant temperature of the hollow cylindrical member 4a. In other words, a material which the conductive member 4b wets and is resistant to heat which is not lower in temperature than the melting point of the conductive member 4b is used for the hollow cylindrical member 4a.

A metal, for example, can be used for the conductive member 4b. Examples of the metal for the conductive member 4b include solder. Tin-lead (Sn—Pb) solder, for example, can be preferably used as the solder for the conductive member 4b. In addition, as the solder for the conductive member 4b, tin-silver-copper (Sn—Ag—Cu) solder, tin-bismuth (Sn—Bi) solder, and the like can be used.

The conductive member 4b is formed at least on one of the surface(s) (both of the outer and inner surfaces or one of the outer and inner surfaces) of the hollow cylindrical member 4a and the inside (the inner space (hollow part)) of the hollow cylindrical member 4a. When the conductive member 4b is formed inside the hollow cylindrical member 4a, it does not matter even if there remains an empty space within the hollow cylindrical member 4a.

The connection member 4 including the hollow cylindrical member 4a and the conductive member 4b, constructed as above, has e.g. a planar size (diameter) S comparable to that of the electrodes 2a and 3a, and a height T set based on the distance to be secured between the circuit board 2 and the semiconductor device 3 after mounting.

The connection member 4 constructed as above is disposed between each electrode 2a of the circuit board 2 and an associated one of the electrodes 3a of the semiconductor device 3, and the conductive member 4b of the connection member 4 is melted and then solidified, whereby one end of the connection member 4 is connected to the electrode 2a and the other end thereof is connected to the associated electrode 3a. This makes it possible to obtain the electronic device 1, illustrated in FIG. 1, in which the semiconductor device 3 is mounted on the circuit board 2 using the connection members 4. Even after the semiconductor device 3 is mounted on the circuit board 2, the connection members 4 each maintain the shape of the hollow cylindrical member 4a or a shape similar thereto.

When mounting the semiconductor device 3 on the circuit board 2, it is possible to connect in advance the connection members 4 to the respective electrodes 3a of the semiconductor device 3, place the semiconductor device 3 having the connection members 4 connected thereto over the circuit board 2, and then melt and solidify the conductive members 4b.

Further, it is possible to form a conductive connection layer (made of a metal, such as solder, solder paste, a conductive resin, or the like) in advance on at least one of each electrode 2a and each electrode 3a, and then connect the connection members 4 to the electrodes 2a and 3a via the connection layer.

By connecting the circuit board 2 and the semiconductor device 3 of the electronic device 1 via the connection members 4 described as above, it is possible to increase the service life of connection portions between the circuit board 2 and the semiconductor device 3. Further, by using the above-described connection members 4, it is possible to effectively suppress occurrence of bridges between adjacent ones of the connection portions. Hereinafter, more detailed descriptions will be given of these points.

To this end, first, for comparison, a description will be given of an electronic device which has the semiconductor device 3 mounted on the circuit board 2 using solder bumps in place of the above-described connection members 4.

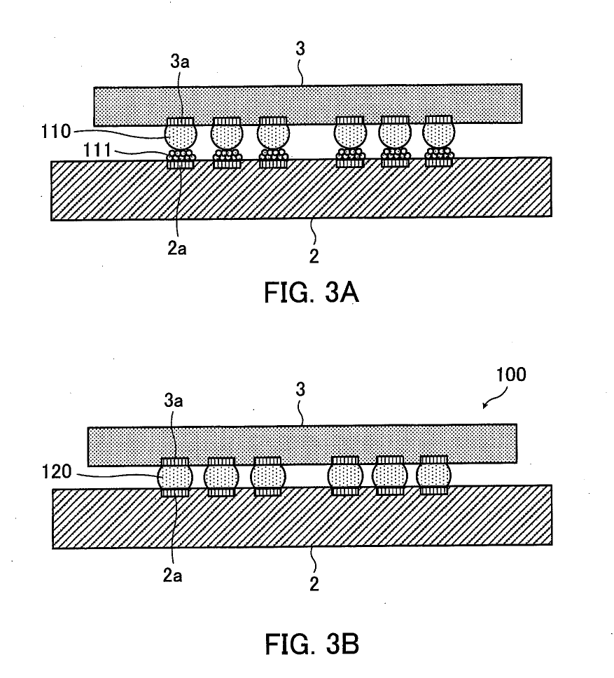

FIGS. 3A and 3B illustrate an example of a method of forming the electronic device, wherein FIG. 3A illustrates a state of the circuit board 2 and the semiconductor device 3 before the semiconductor device 3 is mounted on the circuit board 2, and FIG. 3B illustrates a state of the same after the semiconductor device 3 is mounted on the circuit board 2.

In the example illustrated in FIG. 3A, each of the solder bumps 110 (solder balls are illustrated in FIG. 3A, by way of example) is connected to an associated one of the electrodes 3a of the semiconductor device 3.

When mounting the semiconductor device 3 on the circuit board 2, solder pastes 111 are selectively formed on the respective electrodes 2a of the circuit board 2, and the semiconductor device 3 is disposed over the circuit board 2, as illustrated in FIG. 3A. Then, the solder bumps 110 and the solder pastes 111 associated therewith, respectively, are heated to the melting temperature thereof, whereby as illustrated in FIG. 3B, the solder bumps 110 and the solder pastes 111 are merged, and the electrodes 2a and 3a are electrically connected to each other via respective connection portions 120 formed by the solder bumps 110 and the solder pastes ill merged with each other. At this time, the surface tension of each solder bump 110 and the associated solder paste 111 which are melted and merged with each other is balanced with corresponding part of the weight of the semiconductor device 3 whereby the connection portion 120 is formed into a convex drum shape.

In an electronic device 100 using the solder bumps 110 as described above, some of the connection portions 120 are sometimes broken due to heat generated by the semiconductor device 3 after the semiconductor device 3 is mounted on the circuit board 2.

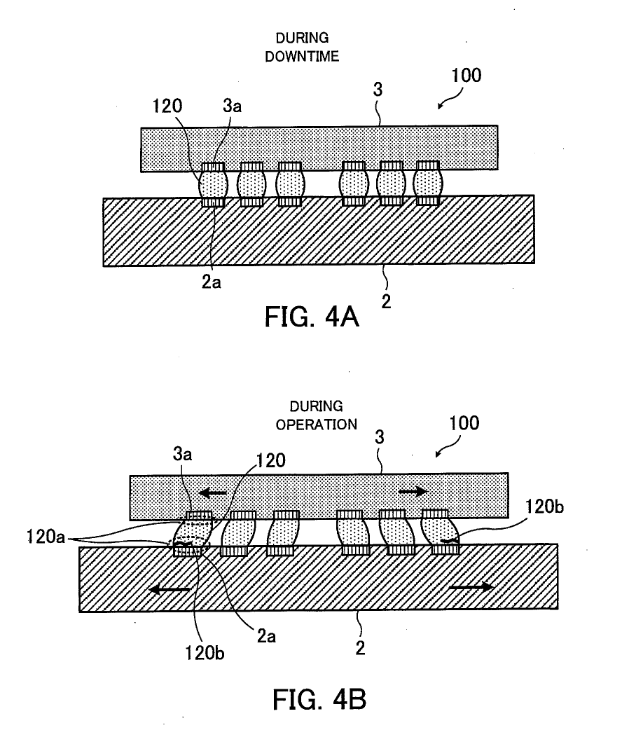

FIGS. 4A and 4B are diagrams illustrating examples of respective states of the electronic device during downtime and during operation, wherein FIG. 4A illustrates an example of the state of the electronic device 100 during downtime, and FIG. 4B illustrates an example of the state thereof during operation.

Part of heat generated by the semiconductor device 3 during operation of the electronic device 100 is released to the outside, and part thereof conducts inside the electronic device 100 (the semiconductor device 3, the circuit board 2, and the connection portions 120 between them).

At this time, as illustrated in FIG. 4B, both the semiconductor device 3 and the circuit board 2 are thermally expanded (in directions indicated by arrows in FIG. 4B), but the semiconductor device 3 and the circuit board 2 are different in the degree of thermal expansion depending on the difference between the materials forming them. The difference between the respective degrees of thermal expansion of the semiconductor device 3 and the circuit board 2 generates stresses in the connection portions 120, which can deform the connection portions 120 each having a fixed shape (convex drum shape), as illustrated in FIG. 4A, into inclined shapes as illustrated in FIG. 4B.

In the case of the connection portions 120 illustrated in FIGS. 4A and 4B, portions 120a of each connection portion 120 close to the electrodes 2a and 3a have a thin and narrow shape, and hence stresses are liable to be concentrated on these portions 120a, which tends to produce cracks 120b therein. Further, the portions 120a are close to the electrodes 2a and 3a, so that in some cases, inter-metallic compounds are formed between the constituents of the electrodes 2a and 3a or diffusion of the constituents of the electrodes 2a and 3a occurs to make the composition of the solder unstable. Therefore, when the electronic device 100 is repeatedly stopped (FIG. 4A) and started (FIG. 4B), the connection portions 120 are sometimes broken by metal fatigue. Such breakage can be more liable to be caused by an increase in the size of the semiconductor device 3, making finer the size of the electrodes 2a and 3a and that of the connection portions 120, or making finer the pitch between the electrodes 2a, that between the electrodes 3a, and that between the connection portions 120.

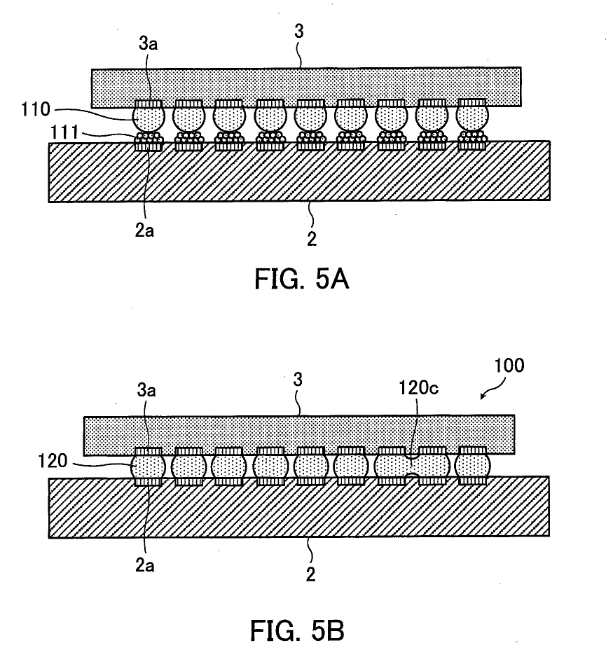

FIGS. 5A and 5B illustrate another example of the method of forming the electronic device, wherein FIG. 5A illustrates a state of the circuit board 2 and the semiconductor device 3 before the semiconductor device 3 is mounted on the circuit board 2, and FIG. 5B illustrates a state of the same after the semiconductor device 3 is mounted on the circuit board 2.

In the example illustrated in FIG. 5A, it is assumed that the electrodes 2a and the electrodes 3a are reduced in pitch. In this case as well, when the semiconductor device 3 is mounted on the circuit board 2 via the solder bumps 110 connected to the semiconductor device 3 and the solder pastes 111 formed on the circuit board 2, the connection portions 120 are each formed into a convex drum shape with a central bulge, as mentioned hereinabove. However, since the connection portions 120 each have such a convex drum shape, if the electrodes 2a and the electrodes 3a are reduced in pitch, adjacent ones of the connection portions 120 can be merged with each other to form a bridge 120c, as illustrated in FIG. 5B.

In contrast, in the electronic device 1 using the connection members 4 illustrated in FIGS. 1 and 2, even after the semiconductor device 3 is mounted on the circuit board 2, each connection member 4 does not have a convex drum shape with a central bulge, but maintains the hollow cylindrical shape which it has before the semiconductor device 3 is mounted on the circuit board 2 or a shape similar to the shape it has before the semiconductor device 3 is mounted on the circuit board 2. Therefore, the connection members 4 do not have a shape having a narrowed portion at a location close to each of the electrodes 2a and 3a, so that it is possible to prevent stress caused by the difference between the respective degrees of thermal expansion of the semiconductor device 3 and the circuit board 2 from concentrating on portions of the connection members 4 close to the electrodes 2a and 3a. As a result, it is possible to increase the service life of the connection portions of the electronic device 1 that connect between the semiconductor device 3 and the circuit board 2.

Further, since the connection members 4 do not have the convex drum shape after the semiconductor device 3 is mounted on the circuit board 2, it is possible to effectively suppress occurrence of bridges. This makes it possible to cope with the above-mentioned reduction in pitch between the electrodes 2a and between the electrodes 3a.

Hereafter, the electronic device using the above-described connection members will be described in more detail. Now, the description will be given by taking, as an example, a case in which a semiconductor package as a semiconductor device is mounted on the circuit board, using the connection members.

First, a description will be given of a first embodiment.

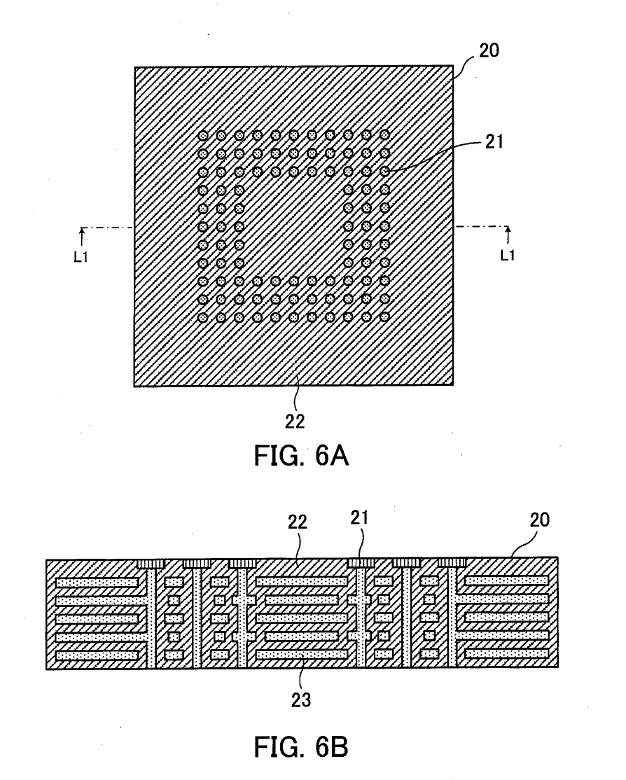

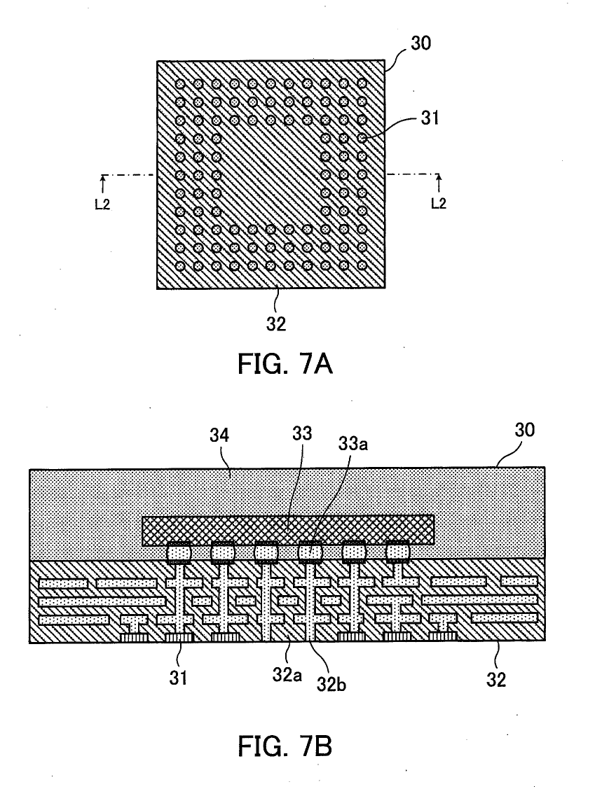

In this embodiment, a circuit board illustrated in FIGS. 6A and 6B and a semiconductor package illustrated in FIGS. 7A and 7B are used.

FIGS. 6A and 6B illustrate an example of the circuit board, wherein FIG. 6A is a schematic plan view of the circuit board, and FIG. 6B is a schematic cross-sectional view taken on line L1-L1 of FIG. 6A. Further, FIGS. 7A and 7B illustrate an example of the semiconductor package, wherein FIG. 7A is a schematic plan view of the semiconductor package, and FIG. 7B is a schematic cross-sectional view taken on line L2-L2 of FIG. 7A.

As the circuit board, there is used a circuit board 20 which has a flat square surface and has a predetermined number of electrodes 21 of a predetermined size arranged at a predetermined pitch on the surface, as illustrated in FIG. 6A. For example, the circuit board 20 has a planar size of 110 mm square and has 420 electrodes 21 with a diameter of 1 mm arranged at a pitch of 1.27 mm on the surface thereof.

As illustrated in FIG. 6B, the circuit board 20 includes an insulating layer 22, and a conductive trace pattern 23 including traces formed in the insulating layer 22 and vias that connect between different traces. The electrodes 21 are electrically connected to the conductive trace pattern 23 formed within the circuit board 20 constructed as above. The electrodes 21 and the conductive trace pattern 23 are formed using Cu, for example.

As illustrated in FIG. 7A, as the semiconductor package, there is used a semiconductor package 30 which has a square flat surface and has a predetermined number of electrodes 31 of a predetermined size arranged at a predetermined pitch on the surface. For example, the semiconductor package 30 has a planar size of 40 mm square and has 420 electrodes 31 with a diameter of 1 mm arranged at a pitch of 1.27 mm on the surface in association with the respective electrodes 21 of the circuit board 20.

As illustrated in FIG. 7B, the semiconductor package 30 includes an interposer 32, and a semiconductor chip 33 which is flip-chip connected to the interposer 32 via bumps 33a, such as solders. Within the semiconductor chip 33, there are formed circuit elements, such as transistors, resistances, and capacitors.

The interposer 32 includes an insulating layer 32a, and a conductive trace pattern 32b including traces formed in the insulating layer 32a and vias that connect between different traces. The electrodes 31 of the semiconductor package 30 are electrically connected to the semiconductor chip 33 via the conductive trace pattern 32b. The electrodes 31 and the conductive trace pattern 32b are formed using Cu, for example.

In the present embodiment, the semiconductor chip 33 connected to the interposer 32 is sealed with a sealing resin 34.

In the following, the illustration of the internal construction of the circuit board 20 except for the electrodes 21, and the illustration of the internal construction of the semiconductor package 30 except for the electrodes 31 are omitted, for convenience sake.

Next, a description will be given of a process step of forming connection members connecting between the circuit board 20 and the semiconductor package 30, constructed as described above.

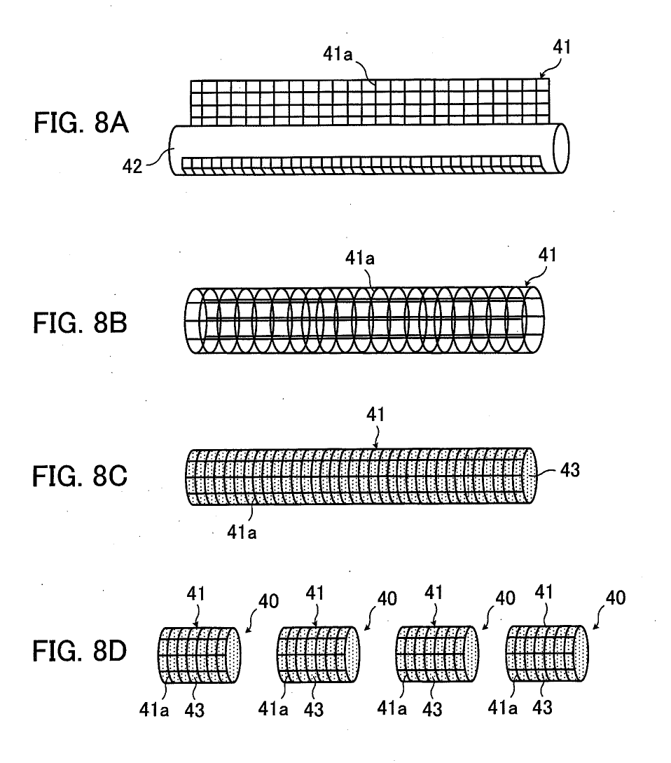

FIGS. 8A to 8D illustrate an example of a process step of forming connection members according to the first embodiment.

First, a sheet-like net 41 is prepared which is made of a mesh of thin wires 41a, illustrated in FIG. 8A. Then, the sheet-like net 41 is wound around a core rod 42, as illustrated in FIG. 8A, such that it is formed into a hollow cylindrical shape. After that, the core rod 42 is pulled out to obtain a hollow cylindrical (tube-like) net 41 (hollow cylindrical member), as illustrated in FIG. 8B.

In the present embodiment, as the net 41, it is possible to use a 200 mesh copper net made of thin wires 41a having a diameter of 0.05 mm. Further, the core rod 42 may have a diameter of 0.5 mm. When the net 41 and the core rod 42, thus configured, are used, the FIG. 8B hollow cylindrical net 41 obtained after pulling out the core rod 42 has a diameter of approximately 0.8 mm to 0.9 mm, for example.

After the hollow cylindrical net 41 is formed as described above, solder 43 as a conductive member is disposed within the net 41, as illustrated in FIG. 8C.

To dispose the solder 43 within the net 41, an Sn—Pb (Sn 63%, Pb 37%) string solder 43 containing turpentine is heated to approximately 250° C. to 300° C. while being brought into contact with the hollow cylindrical net 41. The solder 43 can be melted using e.g. a solder iron or a hot plate set to a predetermined temperature. The molten solder 43 is wet-spread on the surface of the net 41 e.g. by capillary action, and as illustrated in FIG. 8C, fills the inside of the hollow cylindrical net 41.

Furthermore, it is possible to dispose the solder 43 inside the net 41 by dipping the hollow cylindrical net 41 in a tank containing the molten solder 43.

Further, the hollow cylindrical net 41 having the solder 43 disposed therein can be formed by winding the sheet-like net 41 around the string solder (solder 43), or by further heating and melting the string solder of the hollow cylindrical net 41 thus formed.

After the solder 43 is disposed within the hollow cylindrical net 41, the net 41 is cut, as illustrated in FIG. 8D, to a length based on a distance to be secured between the circuit board 20 and the semiconductor package 30 after the semiconductor package 30 is mounted on the circuit board 20 (the height of each connection portion connecting between the circuit board 20 and the semiconductor package 30), e.g. a length corresponding to the distance (e.g. 1 mm). This makes it possible to obtain a plurality of connection members 40 having a predetermined height.

Next, a description will be given of a process step of connecting the connection members 40 to the semiconductor package 30 according to the first embodiment.

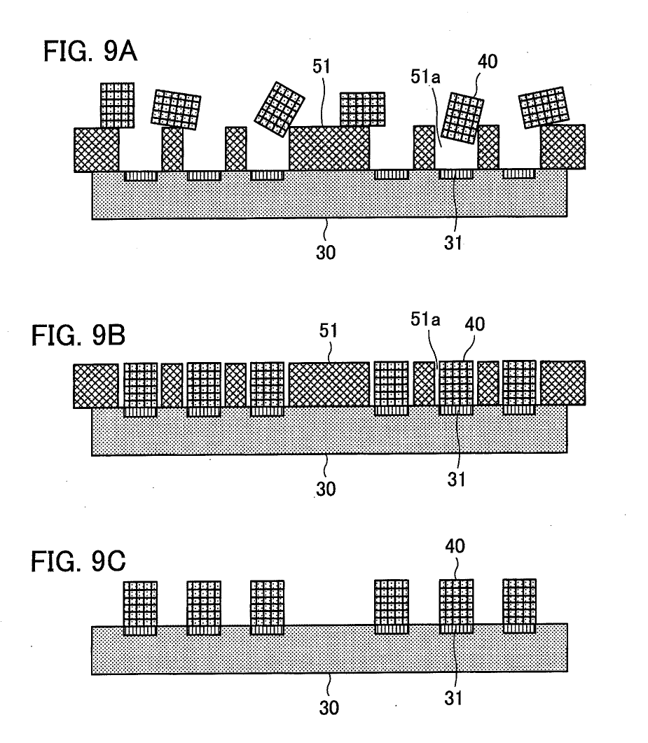

FIGS. 9A to 9C illustrate an example of the process step of connecting the connection members according to the first embodiment, wherein FIG. 9A illustrates a process step of arranging the connection members, FIG. 9B illustrates a process step of heating the connection members, and FIG. 9C illustrates a state of the connection members after connected to the semiconductor package.

First, a rosin-based flux (not illustrated) is applied to the surfaces of the electrodes 31 of the semiconductor package 30.

Then, as illustrated in FIG. 9A, a mask 51 having holes 51a each formed at the same position as that of an associated one of the electrodes 31 is disposed on the semiconductor package 30 after aligning the holes 51a with the electrodes 31, respectively. As the mask 51, it is possible to use e.g. a metal mask made of Kovar, which has a thickness of 1 mm and has holes 51a with a diameter of 1.2 mm formed at a position of the associated one of the electrodes 31.

Then, as illustrated in FIG. 9A, the connection members 40 are dropped, shaken, and rolled on the mask 51 arranged on the semiconductor package 30. Thus, as illustrated in FIG. 9B, the connection members 40 are rolled into the respective openings 51a, and are disposed on the respective electrodes 31 in an erected state (oriented in a direction in which the hollow cylindrical net 41 is erected). From this state, the connection members 40 are arranged and heated on the hot plate to a temperature at which the solder 43 of each connection member 40 is melted, e.g. 250° C., whereby the molten solder 43 and the associated electrode 31 are connected to each other.

Finally, by removing the mask 51, it is possible to obtain the semiconductor package 30 which has the connection members 40 connected to the associated electrodes 31, respectively, as illustrated in FIG. 9C.

The connection members 40 can be arranged on the electrodes 31 not only by the above-described method of using the mask 51 but also by a method of using a manufacturing apparatus, such as a solder ball mounting apparatus, and causing the manufacturing apparatus to operate to automatically arrange the connection members 40, in place of solder balls, on the electrodes 31.

Next, a description will be given of a process step of mounting the semiconductor package 30 on the circuit board 20, according to the first embodiment.

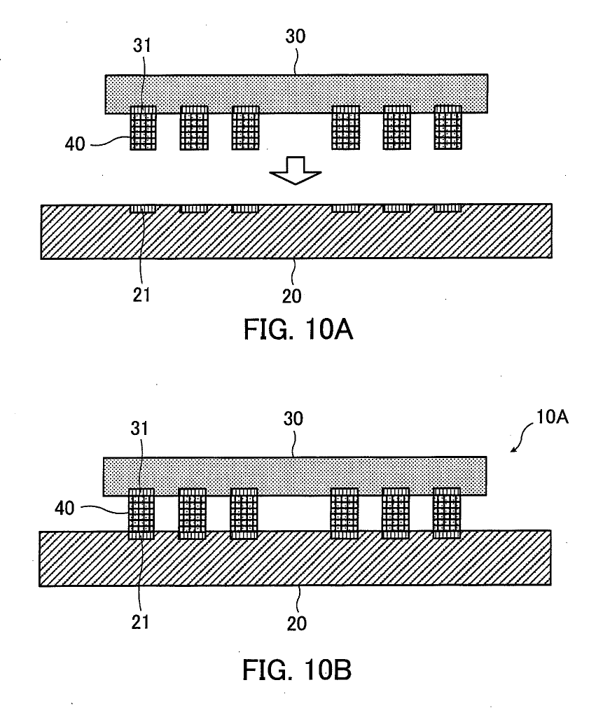

FIGS. 10A and 10B are diagrams illustrating an example of a process step of mounting the semiconductor package according to the first embodiment, wherein FIG. 10A illustrates a state of the circuit board and the semiconductor package before the semiconductor package is mounted on the circuit board, and FIG. 10B illustrates a state of the same after the semiconductor package is mounted on the circuit board.

After the connection members 40 are connected to the semiconductor package 30 as described above, first, as illustrated in FIG. 10A, the semiconductor package 30 is brought to a position above the circuit board 20 such that a side having the connection members 40 disposed thereon is opposed to the circuit board 20, and then the semiconductor package 30 is positioned by aligning the connection members 40 with the electrodes 21, respectively.

Then, in a state where the foremost end of each connection members 40 is brought into abutment with an associated electrode 21, the solder 43 of each connection member 40 is melted by heating in a nitrogen atmosphere using a reflow furnace set such that the temperature around the connection members 40 becomes equal to 220° C. at the highest. This makes it possible to obtain an electronic device 10A, illustrated in FIG. 10B, in which the electrodes 31 of the semiconductor package 30 and the electrodes 21 of the circuit board 20 are connected to each other by the connection members 40, respectively.

In the electronic device 10A constructed as above, the semiconductor package 30 and the circuit board 20 are connected to each other by the connection members 40 each having the solder 43 disposed within the hollow cylindrical net 41. Since the connection members 40 are configured as above, even during operation of the electronic device 10A, it is possible to prevent stress caused by the difference between the degrees of thermal expansion of the semiconductor package 30 and the circuit board 20 from concentrating on portions of the connection members 40 close to the electrodes 21 and 31. As a result, it is possible to increase the service life of the connection portions of the electronic device 10A that connect between the semiconductor package 30 and the circuit board 20.

Further, by using the connection members 40 configured as above, it is possible to maintain the cylindrical shape of the connection portions that connect between the semiconductor package 30 and the circuit board 20, and hence it is possible to effectively suppress occurrence of bridges between adjacent ones of the connection portions.

Although in the above description, Cu is used as the material of the net 41 of each connection member 40, by way of example, the material of the net 41 is not limited to this. For example, a metal having a solder wettability to the solder 43, e.g. a metal comprising one or a combination of two or more of Cu, a Cu alloy, Ni, an Fe—Ni alloy, Pd, a Pd alloy, Pt, and a Pt alloy can be used as the material of the net 41.

Further, although in the above description, the connection members 40 are formed in a flow illustrated in FIGS. 8A to 8D, by way of example, the method of forming the connection members 40 is not limited to this. For example, a method may be employed in which a long hollow cylindrical net 41 is formed, and then the net 41 is cut off to a predetermined length to dispose the solder 43 within each individual cut-off net 41.

Further, although in the above description, the connection members 40 are formed using the net 41, by way of example, this is not limitative, but it is possible to replace the net 41 by a hollow cylindrical member formed by rolling a plate member and dispose the solder 43 within the hollow cylindrical member to thereby form connection members. In this case, one end and the other end of the rolled plate are not necessarily required to be in contact with each other, but they may be separate from each other.

Further, although in the above description, the connection members 40 are directly connected to the electrodes 21 of the circuit board 20, by way of example, this is not limitative, but the connection members 40 can be connected to the electrodes 21 by bringing the connection members 40 into abutment with associated ones of the electrodes 21 after forming a conductive connection layer e.g. of solder paste on each electrode 21 by screen printing or a like method.

Next, a second embodiment will be described.

First of all, a description will be given of a process step of forming connection members according to the second embodiment.

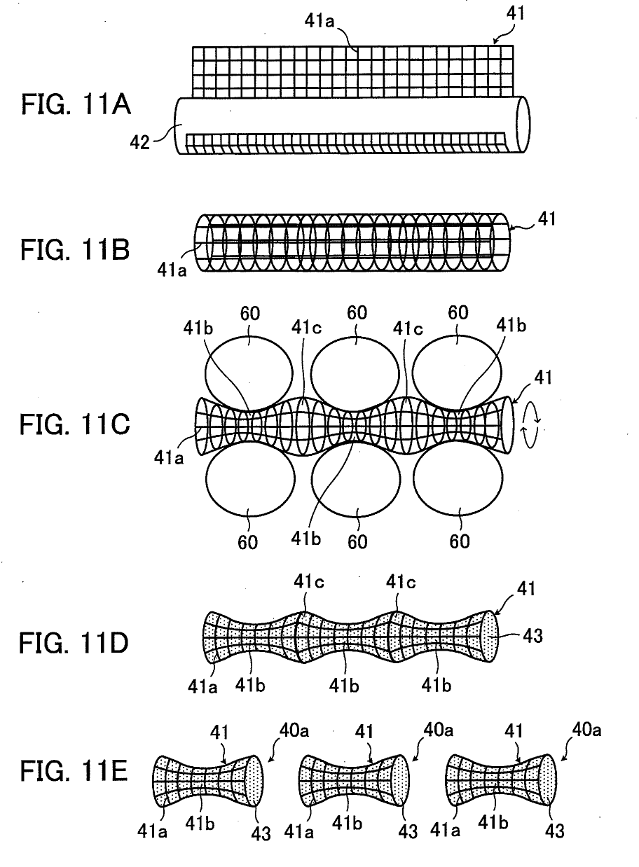

FIGS. 11A to 11E illustrate an example of the process step of forming the connection members according to the second embodiment.

Referring to FIGS. 11A and 11B, first, as described above in the first embodiment, the sheet-like net 41 is wound around the core rod 42, such that it is formed into a hollow cylindrical shape. After that, the core rod 42 is pulled out to obtain a hollow cylindrical (tube-like) net 41.

Then, as illustrated in FIG. 11C, dies 60 having a convex surface with a predetermined curvature radius are pushed against the hollow cylindrical net 41 in a manner sandwiching the hollow cylindrical net 41, and in this state, the hollow cylindrical net 41 is circumferentially rotated (in a direction indicated by arrows in FIG. 11C). This makes it possible to obtain a hollow cylindrical net 41 having narrow portions 41b formed thereon. In doing this, e.g. stainless (SUS304) dies having a curvature radius R of 1.5 mm can be used as the dies 60.

Positions of the narrow portions 41b are set based on the distance to be secured between the circuit board 20 and the semiconductor package 30 after the semiconductor package 30 is mounted on the circuit board (the height of each connection portion connecting between the circuit board 20 and the semiconductor package 30). For example, each narrow portion 41b is formed such that the distance between bulging portions 41c on the opposite sides thereof (e.g. the distance between two adjacent most bulging points of the net 41) becomes equal to a distance (e.g. 1 mm) corresponding to the distance to be secured between the circuit board 20 and the semiconductor package 30 after the semiconductor package 30 is mounted on the circuit board 20.

After forming the hollow cylindrical net 41 having the narrow portions 41b formed as above, as illustrated in FIG. 11D, the solder 43 as a conductive member is disposed therein. The disposition of the solder 43 can be performed in the same manner as described above in the first embodiment, i.e. by the method of heating and melting the Sn—Pb (Sn 63%, Pb 37%) string solder 43 containing turpentine while bringing the string solder 43 into contact with the hollow cylindrical net 41, or the method of dipping the hollow cylindrical net 41 in the tank containing the molten solder 43, for example. The molten solder 43 is wet-spread on the surface of the hollow cylindrical net 41 having the narrow portions 41b formed thereon, and fills the inside of the hollow cylindrical net 41.

It should be noted that after winding the sheet-like net 41 around the string solder (solder 43) to form a hollow cylindrical shape, or further heating the string solder to melt the same and then solidifying the molten solder, the solder and the net 41 can be deformed using the dies 60 to form the narrow portions 41b.

After the solder 43 is disposed within the hollow cylindrical net 41 including the narrow portions 41b, the net 41 having the solder 43 disposed therein is cut through at each bulging portion 41c, as illustrated in FIG. 11E. For example, in a case where the narrow portions 41b are formed such that the distance between the most bulging points of adjacent bulging portions 41c on the opposite sides of one narrow portion 41b becomes equal to the distance to be secured between the circuit board 20 and the semiconductor package 30 after the semiconductor package 30 is mounted on the circuit board 20, the net 41 is cut through at the most bulging points. This makes it possible to obtain a plurality of so-called concave drum shaped connection members 40a each having a predetermined height and having the narrow portion 41b formed at a central portion thereof.

To form such connection members 40a, there may be employed a method in which after forming a long hollow cylindrical net 41 having the narrow portions 41b formed thereon, the hollow cylindrical net 41 is cut off to a predetermined length, and then the solder 43 is disposed within each resultant individual net 41.

Next, a description will be given of a process step of connecting the connection members 40a to the semiconductor package 30 according to the second embodiment.

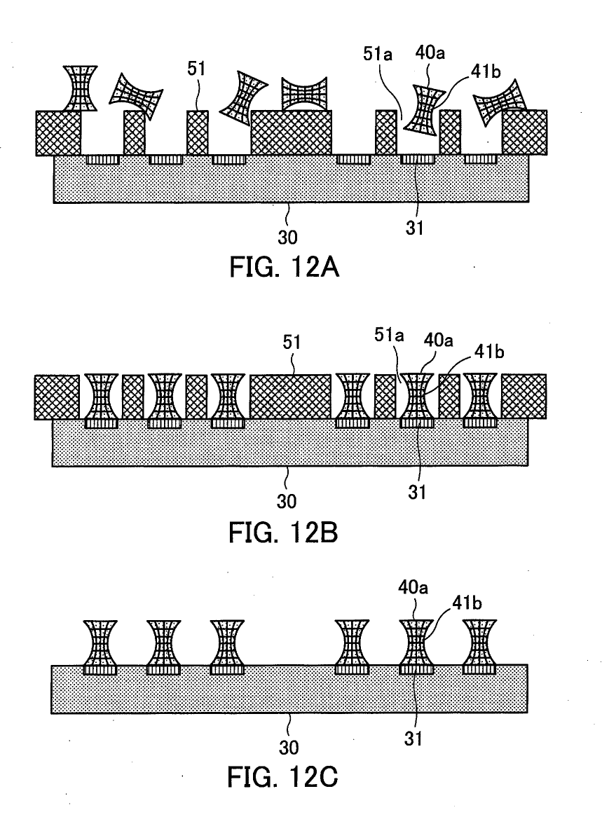

FIGS. 12A to 12C are diagrams illustrating an example of a process step of connecting the connection members according to the second embodiment, wherein FIG. 12A illustrates a process step of arranging the connection members, FIG. 12B illustrates a process step of heating the connection members, and FIG. 12C illustrates a state of the connection members after connected to the semiconductor package.

First, fluxes (not illustrated) are formed on the surfaces of the respective electrodes 31 of the semiconductor package 30. Then, as illustrated in FIG. 12A, a mask 51 having holes 51a each formed at the same position as that of an associated one of the electrodes 31 is arranged on the semiconductor package 30 after aligning the openings 51a of the mask 51 with the electrodes 31, respectively.

Then, using the mask 51, the connection members 40a are rolled into the respective openings 51a thereof, and are arranged, as illustrated in FIG. 12B, on the respective electrodes 31 in an erected state (oriented in a direction in which the hollow cylindrical 41 is erected). From this state, the connection members 40a are heated to a temperature at which the solder 43 is melted, whereby the molten solder 43 and each electrode 31 are connected to each other.

Finally, by removing the mask 51, it is possible to obtain the semiconductor package 30 which has the connection members 40a connected to the electrodes 31, respectively, as illustrated in FIG. 12C.

Next, a description will be given of a process step of mounting the semiconductor package 30 on the circuit board 20 according to the second embodiment.

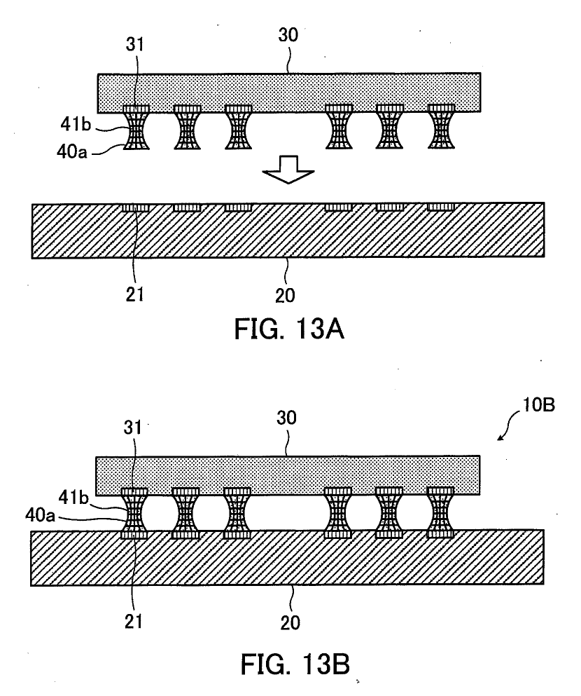

FIGS. 13A and 13B illustrate an example of the process step of mounting the semiconductor package according to the second embodiment, wherein FIG. 13A illustrates a state of the circuit board 20 and the semiconductor package 30 before the semiconductor package is mounted on the circuit board 20, and FIG. 13B illustrates a state of the same after the semiconductor package 30 is mounted on the circuit board 20.

After the connection members 40a are connected to the semiconductor package 30 as described above, first, as illustrated in FIG. 13A, a side having the connection members 40a disposed thereon is caused to be opposed to the circuit board 20, and the semiconductor package 30 is positioned by aligning the connection members 40a with the electrodes 21, respectively. It should be noted that each electrode 21 of the circuit board 20 may have e.g. solder paste (not illustrated) applied thereto in advance by screen printing or a like method.

Then, the foremost end of each connection member 40a is brought into abutment with an associated one of the electrodes 21, and is heated in a nitrogen atmosphere using a reflow furnace set to a predetermined temperature. As a result, an electronic device 10B, illustrated in FIG. 13B, can be obtained in which the electrodes 31 of the semiconductor package 30 and the electrodes 21 of the circuit board 20 are connected to each other by the connection members 40a, respectively.

In the electronic device 10B constructed as described above, the semiconductor package 30 and the circuit board 20 are connected to each other by the respective concave drum shaped connection members 40a each having the narrow portion 41b formed at a central portion thereof. Therefore, even during operation of the electronic device 10B, it is possible to prevent stress caused by the difference between the respective degrees of thermal expansion of the semiconductor package 30 and the circuit board 20 from concentrating on the portions of the connection members 40a close to the electrodes 21 and 31. The stress is liable to occur at the narrow portion 41b where the composition of the solder 43 is relatively stable. As a result, it is possible to increase the service life of the connection portions between the semiconductor package 30 and the circuit board 20.

Further, by using the above-described connection members 40a, the connection portions connecting the semiconductor package 30 and the circuit board 20 can each maintain its cylindrical shape with a narrow central portion. This makes it possible to effectively suppress occurrence of bridges between adjacent ones of the connection portions.

Next, a third embodiment will be described.

First, a description will be given of connection members according to the third embodiment.

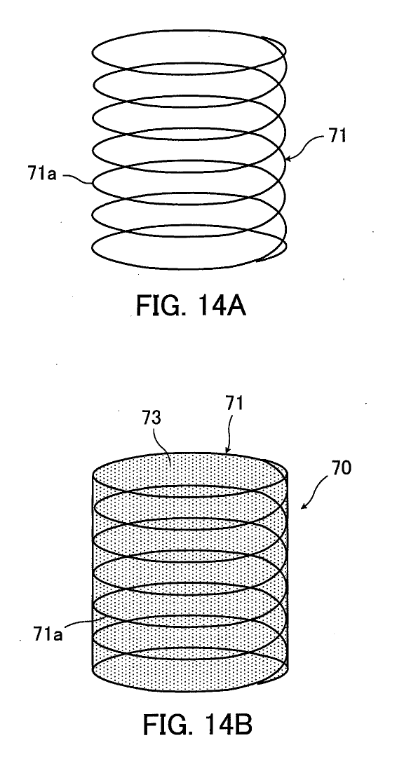

FIGS. 14A and 14B are explanatory diagrams of the connection member according to the third embodiment, wherein FIG. 14A illustrates an example of a hollow cylindrical member, and FIG. 14B illustrates an example of the connection member using the hollow cylindrical member in FIG. 14A.

In this embodiment, as the hollow cylindrical member for a connection member 70, there is used a hollow cylindrical (tube-like) coil 71 (hollow cylindrical member) formed by a spiral of a thin wire 71a.

For the thin wire 71a of the coil 71, it is possible to use a metal wire having a diameter of 0.05 mm, for example. For the thin spiral wire 71a, it is possible to use a metal wire having wettability to the solder 43, e.g. a metal wire formed using one or a combination of two or more of Cu, a Cu alloy, Ni, an Fe—Ni alloy, Pd, a Pd alloy, Pt, and a Pt alloy. A coil having a diameter of 0.8 mm to 1 mm and a height of 1 mm can be used as the above-described coil 71.

The connection member 70 is obtained by disposing solder 73 as a conductive member within the coil 71 illustrated in FIG. 14A, as illustrated in FIG. 14B. The disposition of the solder 43 within the coil 71 can be performed in the same manner as described above in the first embodiment, i.e. by the method of heating and melting Sn—Pb (Sn 63%, Pb 37%) string solder 73 containing turpentine while bringing the string solder 73 into contact with the coil 71, or the method of dipping the coil 71 in a tank containing the molten solder 73, for example. The molten solder 73 is wet-spread on the surface of the coil 71, and fills the inside of the coil 71.

In the third embodiment, the semiconductor package 30 and the circuit board 20 are connected to each other using the connection members 70 thus obtained.

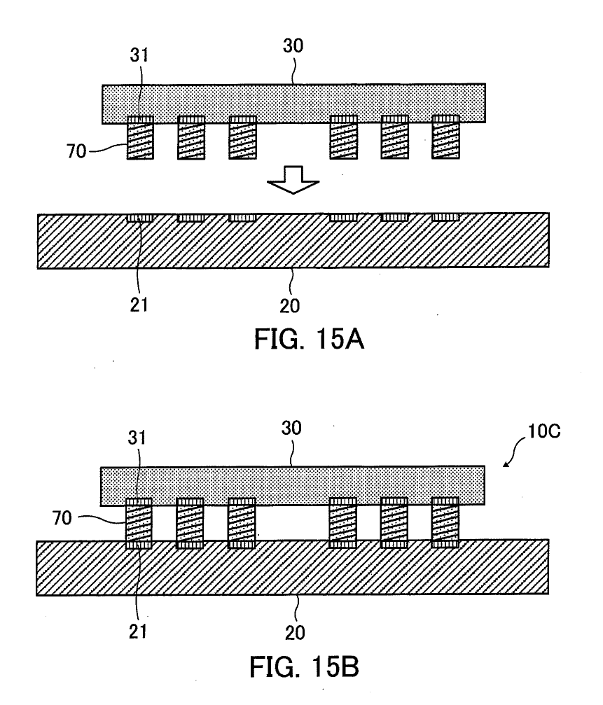

FIGS. 15A and 15B are diagrams illustrating an example of a process step of mounting a semiconductor package according to the third embodiment, wherein FIG. 15A illustrates a state of the circuit board 20 and the semiconductor package 30 before the semiconductor package is mounted on the circuit board 20, and FIG. 15B illustrates a state of the same after the semiconductor package 30 is mounted on the circuit board 20.

First, the connection members 70 are connected to the electrodes 31 of the semiconductor package 30, respectively. Connection of the connection members 70 to the electrodes 31 can be performed in the same manner as described above in the first embodiment (FIGS. 9A to 9C). That is, it is only required that by using the mask 51 having the holes 51a each formed at the same position as that of an associated one of the electrodes 31, the connection members 70 are rolled into the respective openings 51a to dispose the connection members 70 on the respective electrodes 31, and the connection members 70 are heated to a temperature at which the solder 73 is melted, to thereby connect the connection members 70 to the electrodes 31, respectively. After that, the mask 51 is removed.

After the connection members 70 are connected to the semiconductor package 30 as described above, as illustrated in FIG. 15A, a side of the semiconductor package 30 having the connection members 70 disposed thereon is caused to be opposed to the circuit board 20, and the semiconductor package 30 is positioned by aligning the connection members 70 with the electrodes 21, respectively. It should be noted that each electrode 21 of the circuit board 20 may have e.g. solder paste (not illustrated) applied thereto in advance by screen printing or a like method.

Then, the foremost end of each connection member 70 is brought into abutment with an associated one of the electrodes 21, and is heated in a nitrogen atmosphere using a reflow furnace set to a predetermined temperature. As a result, an electronic device 10C, illustrated in FIG. 15B, can be obtained in which the electrodes 31 of the semiconductor package 30 and the electrodes 21 of the circuit board 20 are connected to each other by the connection members 70, respectively.

In the thus-obtained electronic device 10C, the connection portions connecting the semiconductor package and the circuit board 20 can each maintain its cylindrical shape, so that it is possible to increase the service life of the connection portions and effectively suppress occurrence of bridges between adjacent ones of the connection portions.

Next, a fourth embodiment will be described.

First, a description will be given of connection members according to the fourth embodiment.

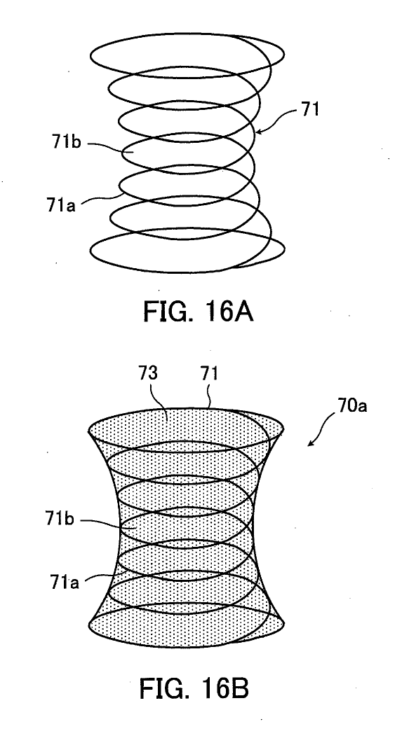

FIGS. 16A and 16B are explanatory diagrams of the connection member according to the fourth embodiment, wherein FIG. 16A illustrates an example of a hollow cylindrical member, and FIG. 16B illustrates an example of the connection member using the hollow cylindrical member in FIG. 16A.

In this embodiment, as the hollow cylindrical member for a connection member 70a, a coil 71 is used which is formed by a spiral of a thin wire 71a and has a narrow portion 71b in a central portion thereof, as illustrated in FIG. 16A. The connection member 70a having the narrow portion 71b in the central portion thereof, as illustrated in FIG. 16B, can be obtained by disposing the solder 73 within the coil 71 illustrated in FIG. 16A, in the same manner as described above in the third embodiment.

In the fourth embodiment, the semiconductor package 30 and the circuit board 20 are connected to each other using the connection members 70a obtained as above.

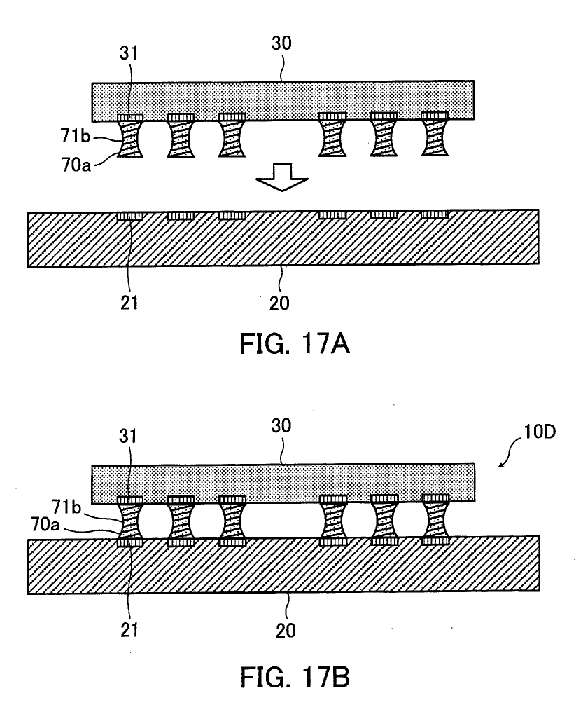

FIGS. 17A and 17B are diagrams illustrating an example of a process step of mounting a semiconductor package according to the fourth embodiment, wherein FIG. 17A illustrates a state of the circuit board 20 and the semiconductor package 30 before the semiconductor package is mounted on the circuit board 20, and FIG. 17B illustrates a state of the same after the semiconductor package 30 is mounted on the circuit board 20.

First, the connection members 70a described above are connected to the respective electrodes 31 of the semiconductor package 30, similarly to the above-described connection members 70 according to the third embodiment. The semiconductor package 30 having the connection members 70a connected thereto is positioned such that it is opposed to the circuit board 20 by performing alignment, as illustrated in FIG. 17A.

Then, the foremost end of each connection member 70a is brought into abutment with an associated one of the electrodes 21 (which may have e.g. solder paste (not illustrated) applied thereto), and is heated at a predetermined temperature. As a result, an electronic device 10D, illustrated in FIG. 17B, can be obtained in which the electrodes 31 of the semiconductor package 30 and the electrodes 21 of the circuit board 20 are connected to each other by the connection members 70a, respectively.

In the thus-obtained electronic device 10D as well, the connection portions connecting the semiconductor package 30 and the circuit board 20 can each also maintain its cylindrical shape with a narrow central portion. This makes it possible to increase the service life of the connection portions and effectively suppress occurrence of bridges between adjacent ones of the connection portions.

Next, a fifth embodiment will be described.

First, a description will be given of a process step of forming connection members according to the fifth embodiment.

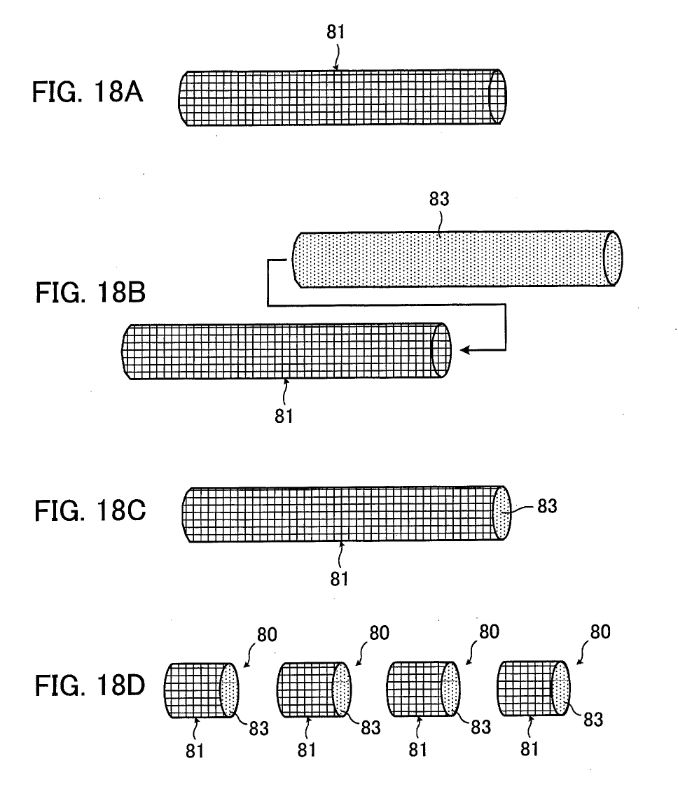

FIGS. 18A to 18D are diagrams illustrating an example of a process step of forming the connection members according to the fifth embodiment.

In the fifth embodiment, a hollow cylindrical (tube-like) resin net 81 (hollow cylindrical member) formed by a mesh of resin-made thin wires (fibers), illustrated in FIG. 18A, is prepared. An aromatic polyamide resin, for example, can be used for a material of the thin wire of the net 81. A net having a thickness of 0.05 mm and an inner diameter of approximately 1 mm, for example, can be used for the hollow cylindrical net 81.

A solder 83 (string solder) is inserted into the hollow cylindrical resin net 81, illustrated in FIG. 18A, as a conductive member, as illustrated in FIGS. 18B and 18C.

After disposing the solder 83 within the net 81, the net 81 containing the solder 83 is cut off to a length (e.g. 1 mm) based on the distance to be secured between the circuit board 20 and the semiconductor package 30 after the semiconductor package 30 is mounted on the circuit board 20 (the height of each connection portion connecting between the circuit board 20 and the semiconductor package 30). This makes it possible to obtain a plurality of connection members 80 having a predetermined height.

Although in the illustrated example, the hollow cylindrical net 81 formed by a mesh of resin-made thin wires is used by way of example, this is not limitative, but a resin-made thin wire formed into a shape of a coil (a hollow cylindrical shape, a shape with a narrow central portion, or the like) can also be used as the hollowing cylindrical member.

Further, although in the illustrated example, the connection members 80 are formed using the resin-made net 81, by way of example, it is also possible to replace the net 81 e.g. by a resin molded article having a hollow cylindrical shape, or a flexible resin sheet rolled into a hollow cylindrical shape, as the cylindrical member. Further, one end and the other end of the rolled sheet are not necessarily required to be in contact with each other, but they may be separate from each other.

In the fifth embodiment, the semiconductor package 30 and the circuit board 20 are connected to each other using the above-described connection members 80, respectively.

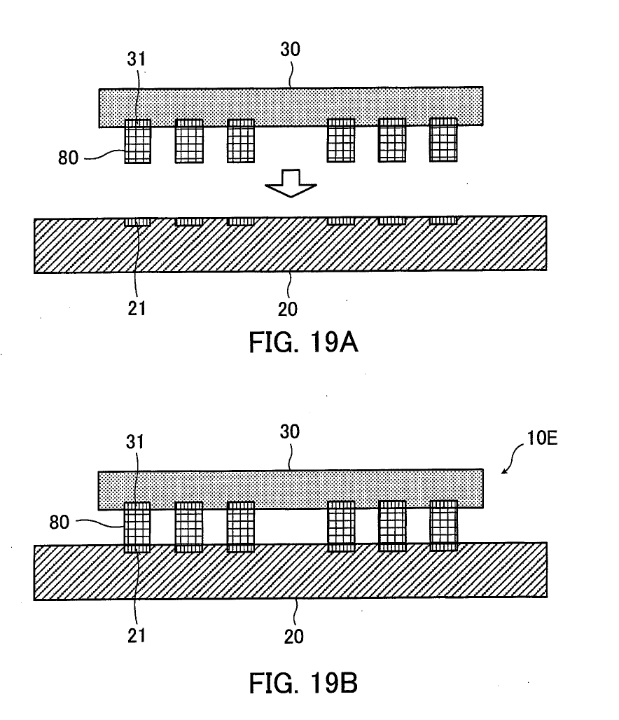

FIGS. 19A and 19B are diagrams illustrating an example of a process step of mounting a semiconductor package according to the fifth embodiment, wherein FIG. 19A illustrates a state of the circuit board 20 and the semiconductor package 30 before the semiconductor package is mounted on the circuit board 20, and FIG. 19B illustrates a state of the same after the semiconductor package 30 is mounted on the circuit board 20.

First, the connection members 80 are connected to the electrodes 31 of the semiconductor package 30, respectively. Connection of the connection members 80 to the electrodes 31 can be performed in the same manner as described above in the first embodiment (FIGS. 9A to 9C). That is, it is only required that by using the mask 51 having the holes 51a each formed at the same position as that of an associated one of the electrodes 31, the connection members 80 are rolled into the respective openings 51a to dispose the connection members 80 on the respective electrodes 31, and the connection members 80 are heated to a temperature at which the solder 83 is melted, to thereby connect the connection members 80 to the electrodes 31, respectively. After that, the mask 51 is removed.

Then, the semiconductor package 30 having the connection members 80 connected thereto is positioned such that it is opposed to the circuit board 20 by performing alignment, as illustrated in FIG. 19A. Then, the foremost end of each connection member 80 is brought into abutment with an associated one of the electrodes 21 (which may have solder paste (not illustrated) applied thereto) and is heated to a predetermined temperature. As a result, an electronic device 10E, illustrated in FIG. 19B, can be obtained in which the electrodes 31 of the semiconductor package 30 and the electrodes 21 of the circuit board 20 are connected to each other by the connection members 80, respectively.

In the thus obtained electronic device 10E as well, the connection portions between the semiconductor package 30 and the circuit board 20 can each also maintain its cylindrical shape, whereby it is possible to increase the service life of the connection portions and effectively suppress occurrence of bridges between adjacent ones of the connection portions.

Next, a sixth embodiment will be described.

First, a description will be given of a process step of forming connection members according to the sixth embodiment.

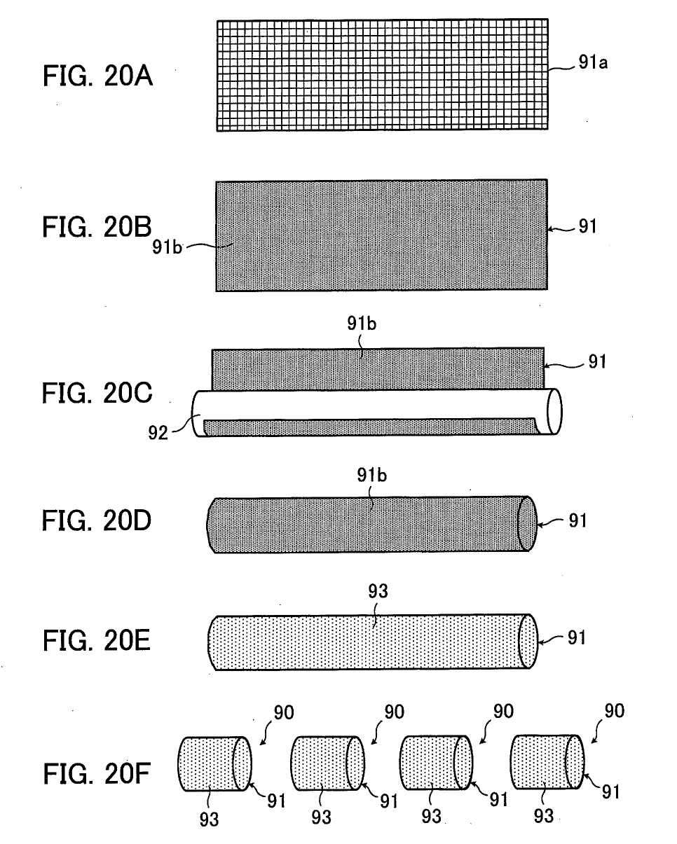

FIGS. 20A to 20F are diagrams illustrating an example of a process step of forming the connection members according to the sixth embodiment.

In the sixth embodiment, first, a resin-made sheet 91a, illustrated in FIG. 20A, is prepared. As the sheet 91a, it is possible to use a fabric sheet made of an aromatic polyamide resin (formed by weaving resin thin wires (fibers)), for example.

Then, a sheet 91a provided with a surface-treated layer 91b, i.e. a surface-treated sheet 91 is prepared by forming the surface-treated layer 91b having wettability to solder 93, referred to hereinafter, on a surface of the sheet 91a, as illustrated in FIG. 20B. As the surface-treated layer 91b, it is possible to form a layer containing a metal having solder wettability, e.g. metal containing one or a combination of two or more of Cu, a Cu alloy, Ni, an Fe—Ni alloy, Pd, a Pd alloy, Pt, and a Pt alloy. The thickness of the surface-treated layer 91b can be set to 0.01 mm, for example. Such a surface-treated layer 91b can be formed on the sheet 91a e.g. by an electroless plating method.

Next, the surface-treated sheet 91 is wound around a core rod 92, as illustrated in FIG. 20C, such that it is formed into a hollow cylindrical shape (having a diameter e.g. of 1 mm). After that, the core rod 92 is pulled out to thereby obtain the surface-treated sheet 91 (hollow cylindrical member) which is wound into a hollow cylindrical (tube-like) shape, as illustrated in FIG. 20D. By virtue of the plastic deformation of the surface-treated layer 91b formed on its surface, the surface-treated sheet 91 wound into the hollow cylindrical shape preserves its hollow cylindrical shape even after the core rod 92 is pulled out therefrom. Further, one end and the other end of the surface-treated sheet 91, which has the core rod 92 pulled out after being wound therearound, are not necessarily required to be in contact with each other, but they may be separate from each other.

After forming the surface-treated sheet 91 having the hollow cylindrical shape, the solder 93 as a conductive member is disposed therein, as illustrated in FIG. 20E. The disposition of the solder 93 can be performed in the same manner as described above in the first embodiment, i.e. by the method of heating and melting the Sn—Pb (Sn 63%, Pb 37%) string solder 93 containing turpentine while bringing the string solder 93 into contact with the surface-treated sheet 91, or the method of dipping the surface-treated sheet 91 in a tank containing the molten solder 93, for example. The molten solder 93 is wet-spread on the surface-treated layer 91b formed on the surface of the surface-treated sheet 91 having the hollow cylindrical shape, and fills the inside of the surface-treated sheet 91 wound as above.

The surface-treated sheet 91, after having the solder 93 disposed therein, is cut off to a length (e.g. 1 mm) based on the distance to be secured between the circuit board 20 and the semiconductor package 30 after the semiconductor package 30 is mounted on the circuit board 20 (the height of each connection portion connecting between the circuit board 20 and the semiconductor package 30), as illustrated in FIG. 20F. This makes it possible to obtain a plurality of connection members 90 having a predetermined height.

In the sixth embodiment, the semiconductor package 30 and the circuit board 20 are connected to each other using the thus obtained connection members 90.

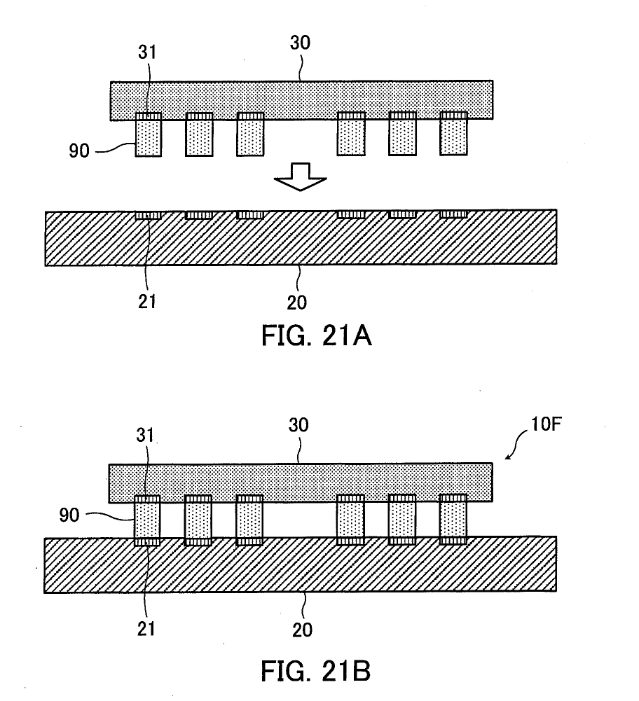

FIGS. 21A and 21B are diagrams illustrating an example of a process step of mounting the semiconductor package according to the sixth embodiment, wherein FIG. 21A illustrates a state of the circuit board 20 and the semiconductor package 30 before the semiconductor package is mounted on the circuit board 20, and FIG. 21B illustrates a state of the same after the semiconductor package 30 is mounted on the circuit board 20.

First, the connection members 90 are connected to the electrodes 31 of the semiconductor package 30, respectively. Connection of the connection members 90 to the electrodes 31 can be performed in the same manner as described above in the first embodiment (FIGS. 9A to 9C). That is, it is only required that by using the mask 51 having the holes 51a each formed at the same position as that of an associated one of the electrodes 31, the connection members 90 are rolled into the respective openings 51a to dispose the connection members 90 on the electrodes 31, respectively, and the connection members 90 are heated to a temperature at which the solder 93 is melted, to thereby connect the connection members 90 to the electrodes 31, respectively. After that, the mask 51 is removed.

Then, the semiconductor package 30 having the connection members 90 connected thereto is positioned such that it is opposed to the circuit board 20 by performing alignment, as illustrated in FIG. 21A. Then, the foremost end of each connection member 90 is brought into abutment with an associated one of the electrodes 21 (which may have e.g. solder paste (not illustrated) applied thereto) and is heated to a predetermined temperature. As a result, an electronic device 10F, illustrated in FIG. 21B, can be obtained in which the electrodes 31 of the semiconductor package 30 and the electrodes 21 of the circuit board 20 are connected to each other by the connection members 90, respectively.

In the thus-obtained electronic device 10F as well, the connection portions between the semiconductor package 30 and the circuit board 20 can each also maintain its cylindrical shape, so that it is possible to increase the service life of the connection portions and effectively suppress occurrence of bridges between adjacent ones of the connection portions.

Although the above descriptions have been given of the electronic devices 10A to 10F, the electronic devices 10A to 10F each can be further provided with a cooling structure (a heat sink).

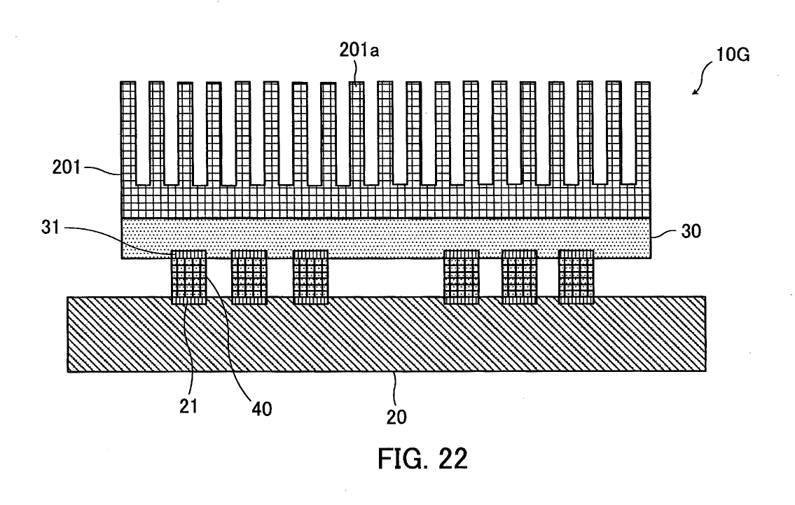

FIG. 22 illustrates an example of an electronic device including a cooling structure.

The electronic device 10G illustrated in FIG. 22 has, by way of example, a cooling structure 201 including a plurality of fins 201a provided on the semiconductor package 30 connected to the circuit board 20 using the connection members 40 described above in the first embodiment. The cooling structure 201 can be formed by a metal material, such as aluminum (Al) or Cu, having excellent thermal conductivity, and is provided on the semiconductor package 30 e.g. via a thermal grease (not illustrated) or an adhesive agent (not illustrated) having a predetermined thermal conductivity. The semiconductor package 30 and the circuit board 20 are thermally connected to each other.

By providing such a cooling structure 201, heat generated in the semiconductor package 30 (not necessarily all the generated heat) is transferred to the cooling structure 201, and is efficiently released therefrom. As a result, it is possible to effectively suppress an excessive rise in temperature of the semiconductor package 30 and deformation (expansion, contraction, or warpage) of the circuit board 20 and the semiconductor package 30, thereby making it possible for the electronic device 10G to stably operate for a long time period.

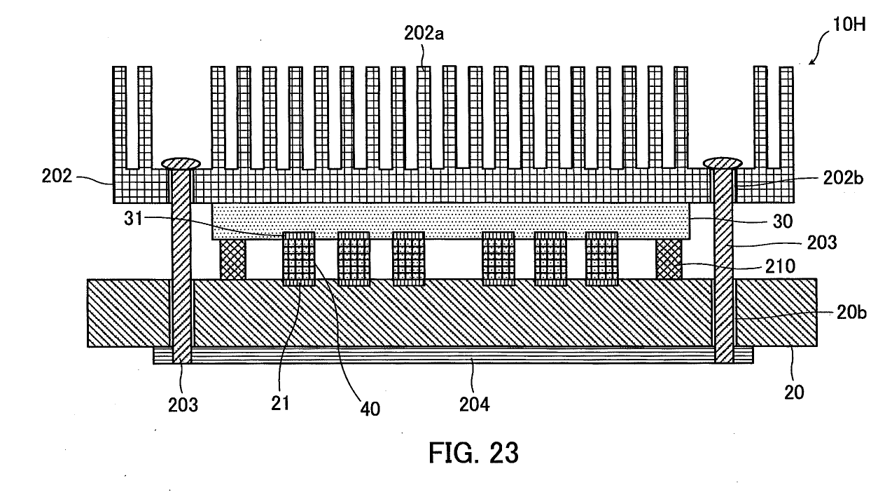

Further, FIG. 23 illustrates another example of an electronic device including a cooling structure.

The electronic device 10H as illustrated in FIG. 23 has, by way of example, the cooling structure 202 including a plurality of fins 202a provided on the semiconductor package 30 connected to the circuit board 20 using the connection members 40 described above in the first embodiment. The cooling structure 202 can be formed by a metal material, such as Al or Cu, having excellent thermal conductivity, and is provided on the semiconductor package 30 e.g. via a thermal grease (not illustrated) or an adhesive agent (not illustrated) having a predetermined thermal conductivity.

The cooling structure 202 is provided with through holes 202b through which a plurality of fixing screws 203 extend, respectively. Further, in the illustrated example, the circuit board 20 as well is provided with through holes 20b through which the fixing screws 203 extend, respectively. Each fixing screw 203 is inserted through the through holes 202b and 20b, and is screwed into a screw-receiving plate 204 on a side of the circuit board 20 opposite from the semiconductor package 30. The electronic device 10H is thus configured such that the cooling structure 202 is firmly fixed using the fixing screws 203.

FIG. 23 illustrates a case where stand-offs 210 are provided between the circuit board 20 and the semiconductor package 30 for maintaining the distance therebetween constant.

By using the electronic device 10H as well, it is possible to effectively suppress an excessive rise in temperature of the semiconductor package 30 and deformation (expansion, contraction, or warpage) of the circuit board 20 and the semiconductor package 30, thereby making it possible to cause the electronic device 10H to stably operate for a long time period.

Although in the illustrated examples, the semiconductor package 30 is connected to the circuit board 20 using the connection members 40 described above in the first embodiment, by way of example, this is not limitative, but it is possible to dispose the cooling structure 201 or 202 in the electronic devices in which the semiconductor package 30 is connected to the circuit board 20 using the connection members 40a, 70, 70a, 80 and 90 described in the second to sixth embodiments, similarly to the electronic devices illustrated in FIGS. 22 and 23.

Further, the above-described electronic devices 10A to 10F, and electronic devices (electronic devices 10G, 10H, etc.) having the cooling structure 201 or 202 provided thereon are applicable to various electronic equipment (electronic devices).

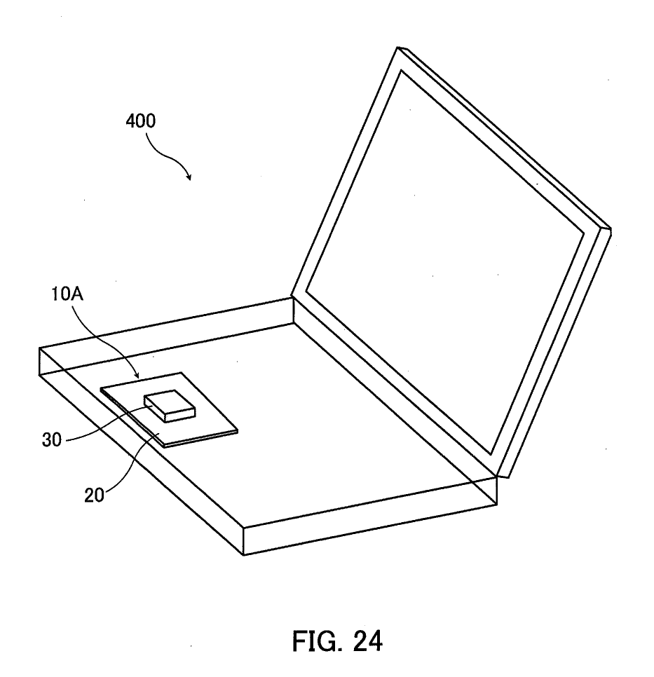

FIG. 24 is a schematic diagram illustrating an example of electronic equipment.

FIG. 24 illustrates a notebook computer which is one of information processing apparatuses, as electronic equipment 400, by way of example. The electronic equipment 400 incorporates e.g. the electronic device 10A in which the semiconductor package 30 is mounted on the circuit board 20 (the connection members 40 are omitted from illustration). In FIG. 24, the internal structure of the electronic equipment 400 except for the electronic device 10A is omitted from illustration.

The electronic devices 10B to 10H can be applied to the electronic equipment 400 in place of the electronic device 10A illustrated in FIG. 24. Further, although in the example illustrated in FIG. 24, the electronic device 10A or the like is applied to the notebook computer, the electronic device 10A or the like can be applied to various electronic equipment, such as a desktop computer, a server computer, a semiconductor manufacturing apparatus, and a semiconductor test device.

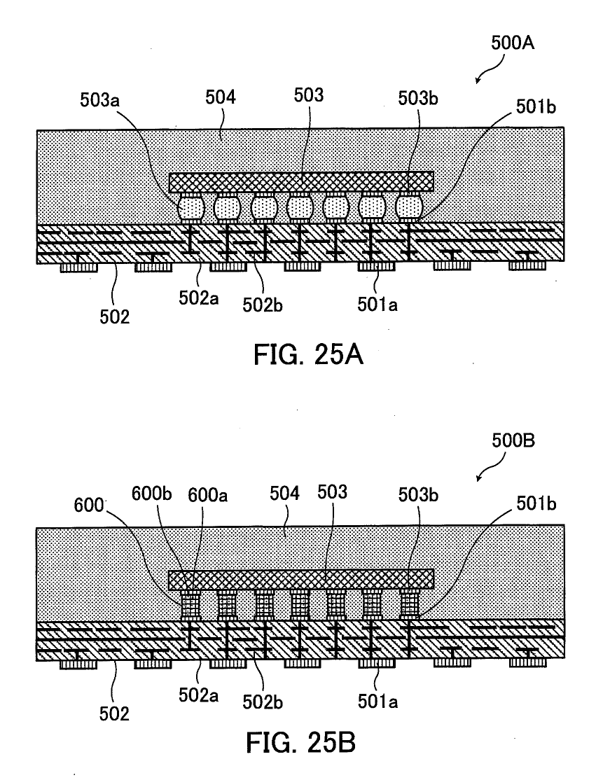

Further, in place of the semiconductor package 30 described above, semiconductor packages constructed as illustrated in FIGS. 25A to 27B, described hereinafter, can be applied to the above-described electronic devices 10A to 10H.

A semiconductor package 500A illustrated in FIG. 25A has a construction similar to that of the semiconductor package 30 illustrated in FIGS. 7A and 7B. More specifically, a semiconductor chip 503 including electrodes 503b is flip-chip connected to an interposer 502 including an insulating layer 502a, a conductive trace pattern 502b, and electrodes 501a and 501b, via bumps 503a. The semiconductor chip 503 connected to the interposer 502 is sealed with a sealing resin 504.

On the other hand, a semiconductor package 500B illustrated in FIG. 25B has a structure in which each of the bumps 503a of the semiconductor package 500A is replaced by a connection member 600. As the connection member 600, it is possible to use a connection member including a cylindrical member 600a, and a conductive member 600b disposed in the cylindrical member 600a, as described above. For example, as the connection member 600, it is possible to use any of the above-described connection members 40, 40a, 70, 70a, 80, and 90. In this case, the planar size (diameter) of the connection members 40, 40a, 70, 70a, 80, and 90 is set to a size corresponding to the planar size of the electrodes 503b of the semiconductor chip 503 and the electrodes 501b of the interposer 502. As illustrated in FIG. 25B, when the semiconductor chip 503 and the interposer 502 are connected to each other using the connection members 600, it is possible to prevent stress from concentrating on portions of the connection members 600 close to the electrodes 503b and 501b, whereby it is possible to increase the service life of the connection portions between the semiconductor chip 503 and the interposer 502.

For the above-described electronic devices 10A to 10H, it is possible to use not only the semiconductor package 500A illustrated in FIG. 25A but also the semiconductor package 500B illustrated in FIG. 25B.

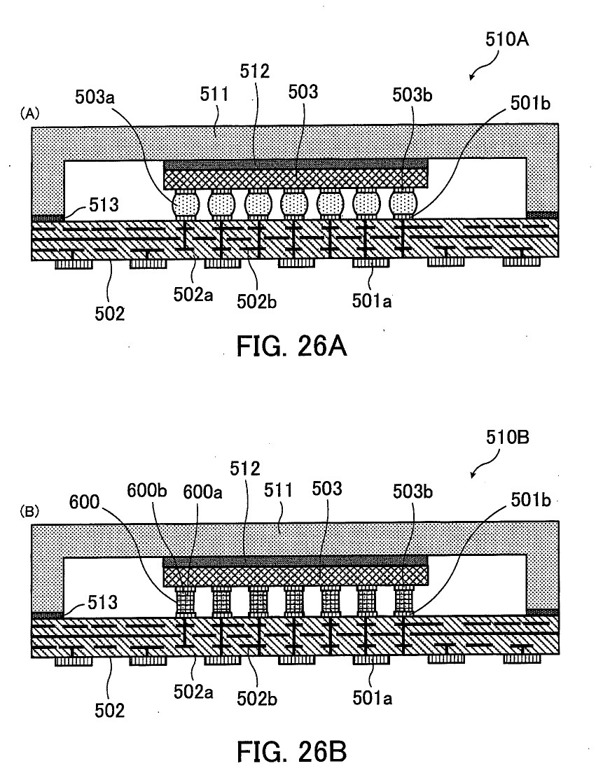

Further, a semiconductor package 510A illustrated in FIG. 26A has a structure in which the semiconductor chip 503 flip-chip connected to the interposer 502 via the bumps 503a is covered with a metal cover 511. The metal cover 511 is joined (thermally connected) to the upper surface of the semiconductor chip 503 mounted on the interposer 502, by a thermal conductive member 512, such as a thermal grease or an adhesive agent having a predetermined thermal conductivity. Furthermore, the metal cover 511 has an edge thereof joined to the upper surface of the interposer 502 using an adhesive material 513. In the case of the electronic devices 10G and 10H provided with the cooling structure 201 or 202, the cooling structure 201 or 202 is provided on the metal cover 511 using e.g. the thermal grease or the adhesive agent having a predetermined thermal conductivity. In this case, heat generated in the semiconductor chip 503 (not necessarily all the generated heat) is transferred e.g. to the thermal conductive member 512 and the metal cover 511, and is then transferred to the cooling structure 201 or 202, for being released therefrom.

On the other hand, a semiconductor package 510B illustrated in FIG. 26B has a structure in which each of the bumps 503a of the semiconductor package 510A illustrated in FIG. 26A is replaced by a connection member 600. For example, as the connection member 600, it is possible to use any of the connection members 40, 40a, 70, 70a, 80, and 90 having a predetermined size depending on the size of the electrodes 503b and 501b. Also when the metal cover 511 illustrated in FIG. 26B is used, the semiconductor chip 503 and the interposer 502 are connected to each other using the connection members 600, whereby it is possible to prevent stress from concentrating on portions of the connection members 600 close to the electrodes 503b and 501b to increase the service life of the connection portions. Furthermore, by connecting the semiconductor chip 503 and the interposer 502 using the above-described connection members 600, it is possible to maintain the shape of each connection section to effectively suppress occurrence of bridges between adjacent ones of the connection portions.

For the above-described electronic devices 10A to 10H, it is also possible to use the semiconductor package 510A in FIG. 26A or the semiconductor package 510B in FIG. 26B.

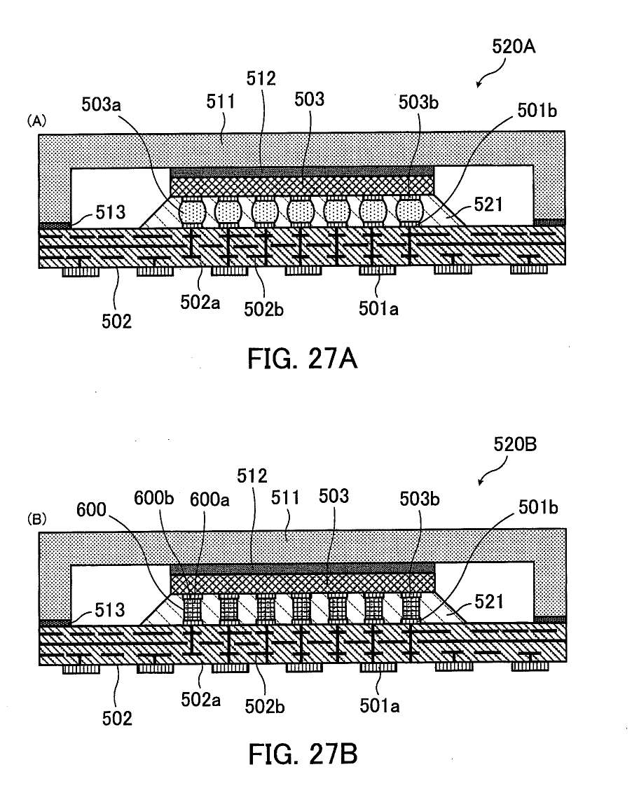

Further, semiconductor packages 520A and 520B illustrated in FIGS. 27A and 27B, respectively, are distinguished from the respective semiconductor packages 510A and 510B illustrated in FIGS. 26A and 26B, respectively, in that connection portions between the interposer 502 and the semiconductor chip 503 are sealed with a sealing resin 521. By providing such a sealing resin 521, it is possible to further enhance the strength of connection between the interposer 502 and the semiconductor chip 503.

For the above-described electronic devices 10A to 10H, it is also possible to use the semiconductor package 520A in FIG. 27A or the semiconductor package 520B in FIG. 27B.

In the above, the descriptions have been given of the connection between the semiconductor package 30 and the circuit board 20 using the connection members 40, 40a, 70, 70a, 80, and 90, and the connection between the semiconductor chip 503 and the interposer 502 using the connection members 600. Next, a description will be given of an example of a method of evaluating reliability of the connections, and an example of the results of evaluation of the connection reliability by the method.

As the method of evaluating reliability of the connections, there is used a heat cycle test performed by repeatedly raising and lowering the temperature of a mounting structure in which a semiconductor device, such as a semiconductor package or a semiconductor chip, is flip-chip connected to a substrate, such as a circuit board or an interposer, within a predetermined temperature range. Further, there is also used a method of evaluating the connection reliability of the mounting structure by a bending test which repeatedly generates mechanical stress on the mounting structure. Here, a description will be given of the evaluation of the connection reliability by the bending test.

First, a description will be given of an example of the mounting structure (sample) used in the bending test.

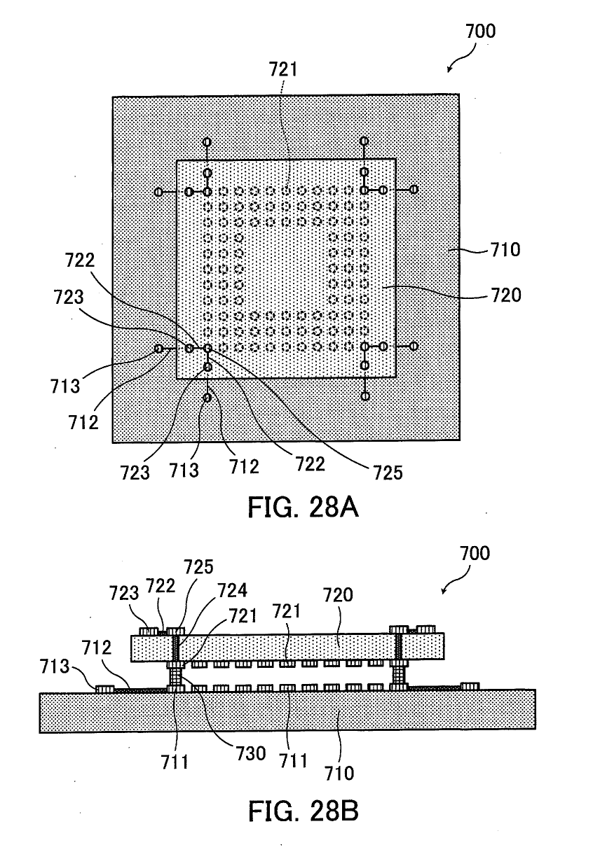

FIGS. 28A and 28B are diagrams illustrating an example of a sample, wherein FIG. 28A is a plan view of the sample and FIG. 28B is a side view of the same.

FIGS. 28A and 28B illustrate a sample 700 in which a semiconductor package 720 is mounted on a circuit board 710. As the circuit board 710 and the semiconductor package 720, it is possible to use not only a circuit board and a semiconductor package which can be sold as products but also a circuit board and a semiconductor package which are produced for test purposes based on the respective designs of the products.

Here, the circuit board 710 having a planar size of 110 mm square, and the semiconductor package 720 having a planar size of 40 mm square are used, by way of example. The circuit board 710 and the semiconductor package 720 have electrodes 711 and 721 arranged at positions corresponding to each other on opposed surfaces thereof, respectively. The electrodes 711 and 721 each have a diameter of 0.76 mm, for example, and 520 of both of them are arranged on the respective opposed surfaces of the circuit board 710 and the semiconductor package 720 at a pitch of 1.27 mm. Out of the large number of electrodes 711 and 721 opposed to each other, only electrodes 711 and 721 arranged at four corners of the circuit board 710 and the semiconductor package 720 are connected by connection members 730, respectively.

Two leads 712, and terminals 713 arranged at respective ends of the two leads 712, are electrically connected to an associated one of the electrodes 711 arranged at the respective four corners of the circuit board 710. On the other hand, two leads 722 arranged on a surface of the semiconductor package 720, opposite from the electrodes 721, and terminals 723 arranged at respective ends of the two leads 722 are electrically connected to an associated one of the electrodes 721 arranged at the respective four corners of the semiconductor package 720 via a via 724 and an electrode 725.

The connection members 730 connecting between the electrodes 711 at the four corners of the circuit board 710 and the electrodes 721 at the four corners of the semiconductor package 720 can be formed, for example, by winding a 200 mesh copper net having a diameter of 0.05 mm around a metal wire having a diameter of 0.3 mm, then pulling out the metal wire to obtain a hollow cylindrical net, and disposing solder within the hollow cylindrical net. It is possible to use e.g. Sn—Pb solder as the solder. Further, the disposition of the solder within the hollow cylindrical net can be performed in the same manner as described above in the first embodiment. When such a metal wire or a net is used, a member obtained after the disposition of the solder has a diameter of approximately 0.6 mm to 0.7 mm. By cutting off the thus obtained member to a length e.g. of 2 mm, separate connection members 730 are formed, and by using the connection members 730, the sample 700 having the semiconductor package 720 mounted on the circuit board 710 is formed.

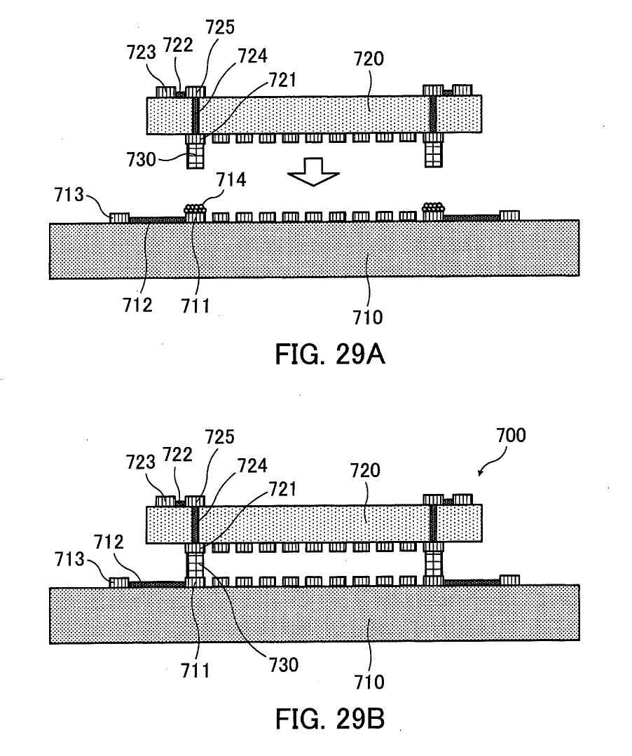

FIGS. 29A and 29B are diagrams illustrating an example of a method of forming a sample, wherein FIG. 29A illustrates a state of the sample before the semiconductor package 720 is mounted on the circuit board 710, and FIG. 29B illustrates a state of the same after the semiconductor package 720 is mounted on the circuit board 710.

When mounting the semiconductor package 720 on the circuit board 710, first, the connection members 730 are connected to the electrodes 721 at the four corners of the semiconductor package 720, respectively. This connection of the connection members 730 can be performed e.g. as follows:

Fluxes are formed on the surfaces of the respective electrodes 721 of the semiconductor package 720, and a mask having openings formed at the respective positions of the electrodes 721 at the four corners of the semiconductor package 720 is disposed on the semiconductor package 720 after aligning the openings with associated ones of the electrodes 721 at the four corners. As the mask, it is possible to use e.g. a metal mask made of Kovar, having a thickness of 1 mm to 2 mm. Then, the connection members 730 are rolled into the openings of the mask to dispose them on the respective electrodes 721 at the four corners of the semiconductor package 720, in an erected state (oriented in a direction in which the hollow cylindrical net is erected). From this state, the connection members 730 are heated to a temperature at which the solder is melted, whereby the molten solder and the electrodes 721 are connected to each other. Finally, the mask used for rolling the connection members 730 is removed, whereby it is possible to obtain the semiconductor package 720 in which the connection members 730 are connected to the associated electrodes 721 at the four corners of the semiconductor package 720, respectively.

On the other hand, as for the circuit board 710, a mask, e.g. a metal mask having a thickness of 0.15 mm, which has openings formed at the respective positions of the electrodes 711 at the four corners of the circuit board 710, is disposed on the circuit board 710 after aligning the openings with associated ones of the electrodes 712 at the four corners. Then, a solder paste 714 is printed on the electrodes 711 at the four corners, as illustrated in FIG. 29A. As the solder paste 714, it is possible to use the Sn—Pb solder, for example.

As illustrated in FIG. 29A, the semiconductor package 720 having the connection members 730 connected thereto is brought to a position above the circuit board 710 printed with the solder paste 714, as described above, such that a side of the semiconductor package 720 having the connection members 730 connected thereto is opposed to the circuit board 710, and is then positioned by performing alignment. Then, the foremost ends of the connection members 730 are brought into contact with the solder paste 714 on the electrodes 711, and are heated in a nitrogen atmosphere using a reflow furnace set such that the temperature around the connection members 730 becomes equal to 220° C. at the highest to thereby melt the solder of the connection members 730 and the solder paste 714. This makes it possible to obtain the sample 700 in which the electrodes 711 at the four corners of the circuit board 710 and the associated electrodes 721 at the four corners of the semiconductor package 720 are connected to each other by the connection members 730, respectively, as illustrated in FIG. 29B.

The bending test is performed on the sample 700 thus obtained to thereby evaluate the connection reliability of connection portions between the circuit board 710 and the semiconductor package 720. Here, for comparison, the bending test is performed on a sample (comparative sample) in which the electrodes 711 at the four corners of the circuit board 710 and the associated electrodes 721 at the four corners of the semiconductor package 720 are connected to each other by solder bumps formed by solder balls, respectively, for evaluation of the connection reliability of the comparative sample.

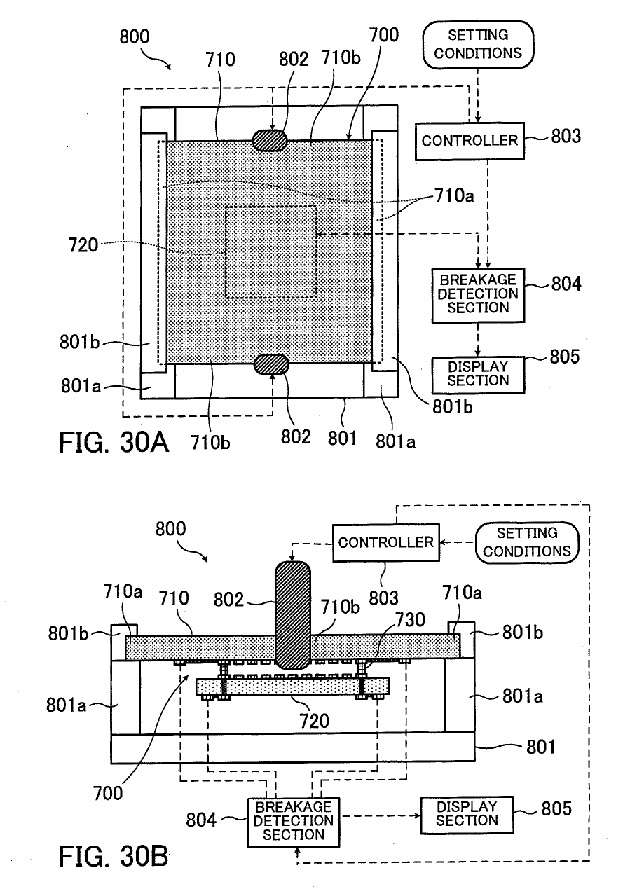

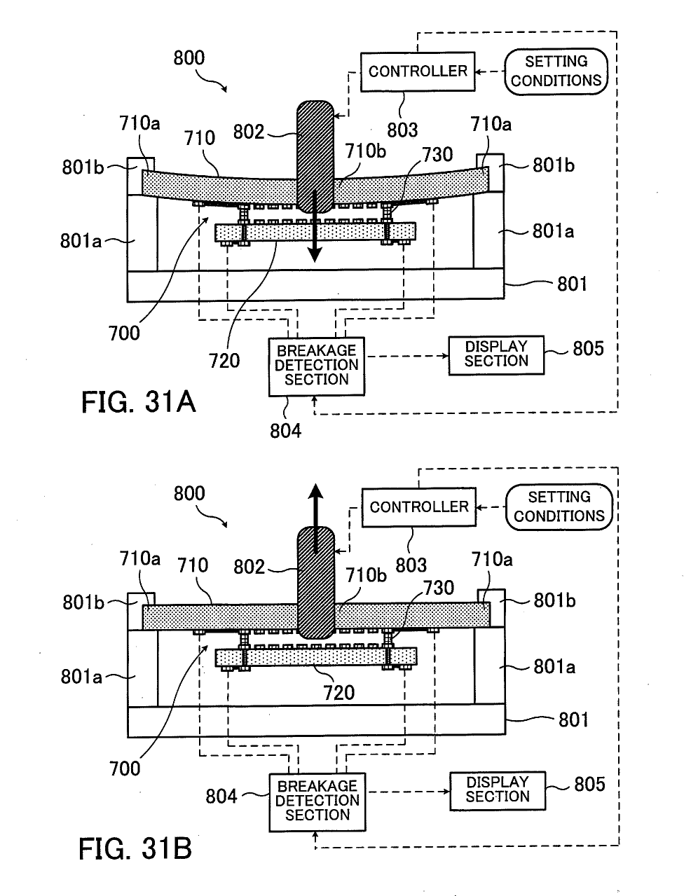

FIGS. 30A and 30B are diagrams illustrating an example of the construction of a bending device for use in the bending test, wherein FIG. 30A is a plan view of essential elements of the bending device, and FIG. 30B is a side view of the essential elements. Further, FIGS. 31A and 31B are explanatory diagrams of an example of the bending test, wherein FIG. 31A illustrates a first state of the bending test, and FIG. 31B illustrates a second state thereof. FIGS. 30A and 30B and FIGS. 31A and 31B illustrate the sample 700 using the connection members 730, by way of example.

As illustrated in FIGS. 30A and 30B and FIGS. 31A and 31B, the bending device 800 for use in the bending test comprises a support stand 801, pushers 802, a controller 803, a breakage detection section 804, and a display section 805.

The support stand 801 includes a pair of support sections 801a which are arranged such that they can support unidirectionally opposite edges 710a of the circuit board 710 having the semiconductor package 720 mounted thereon, and fixing sections 801b for fixing the opposite edges 710a of the circuit board 710 to the support sections 801a. The circuit board 710 having the semiconductor package 720 mounted thereon is placed on the support sections 801a of the support stand 801 with the semiconductor package 720 facing toward the support stand 801, and is fixed to the support sections 801a by the fixing sections 801b.

As illustrated in FIGS. 30A and 30B and FIGS. 31A and 31B, the foremost ends of the pushers 802 are configured to be capable of holding respective opposite edges 710b of the circuit board 710 placed on the support stand 801, which are opposite in a direction orthogonal to a direction in which the opposite edges 710a are opposite to each other. As illustrated in FIGS. 31A and 31B, the pushers 802 are configured to vertically move toward and away from the support stand 801 while holding the opposite edges 710b of the circuit board 710 with the foremost ends thereof. The vertical motion of the pushers 802 is performed at a predetermined amplitude and a predetermined frequency. The vertical motion of the pushers 802 performed at the predetermined amplitude and the predetermined frequency is controlled by the controller 803. The bending device 800 is configured such that the conditions (amplitude and frequency) for the vertical motion of the pushers 802 can be set in advance in the bending device 800. The controller 803 causes the pushers 802 to vertically move according to the set conditions.

In the bending test using the bending device 800, first, the position of the pushers 802 holding the circuit board 710 fixed to the support stand 801 before the start of the bending test is set as a reference position. From the reference position, the pushers 802 are pushed toward the support stand 801 by a predetermined amount (FIG. 31A), and then the pushers 802 are returned again to the original reference position (FIG. 31B). The motion of the pushers 802 that are pushed from the reference position and are returned again to the original reference is set as one cycle. In the illustrated example, under a temperature environment of room temperature (approximately 25° C.), the one-cycle motion of the pushers 802 that are pushed from the reference position toward the support stand 801 by 1.5 mm and are returned again to the original reference position is performed at a frequency of 0.5 Hz.

When the above-described bending test by the pushers 802 is performed, stress is generated in the connection portions between the circuit board 710 and the semiconductor package 720, and eventually, the connection portions are broken by metal fatigue. The stress generated at the connection portions connecting the circuit board 710 and the semiconductor package 720 is liable to increase in the connection portions at the four corners, implemented using the connection members 730 or the solder bumps. Here, as to only the connection portions at the four corners, where such large stress is liable to occur, the liability (or difficulty) of occurrence of breakage, i.e. the connection reliability is evaluated using the sample 700 using the connection members 730 and the comparative example using the solder bumps.

During the bending test, breakage of the connection portions between the circuit board 710 and the semiconductor package 720 can be detected by causing electric current to flow through each of the connection portions at the four corners and monitoring a change in voltage (electric resistance) caused by the electric current. The detection of the breakage of each connection portion can be performed by a four-terminal method, using the leads 712 and 722, the terminals 713 and 723, the via 724 and the electrode 725, formed in advance on the circuit board 710 and the semiconductor package 720.

For example, in the case of the sample 700, illustrated in FIGS. 28A and 28B, in which the connection members 730 are used, first, electric current is caused to flow between one of two pairs of the leads 712 and terminals 713 connected to the associated electrode 711 and one of the two pairs of the leads 722 and terminals 723 connected to the associated electrode 721 via the via 724 and the electrode 725. For example, 160 mA of direct current is caused to flow between the terminals 713 and 723. Then, voltage between the other of the two pairs of the leads 712 and terminals 713 connected to the electrode 711 and the other of the two pairs of the leads 722 and terminals 723 connected to the electrode 721 is measured. Also in the case of the comparative sample using the solder bumps, similarly to the case of the sample 700, electric current is caused to flow to measure voltage.

Electric current caused to flow through each connection portion between the circuit board 710 and the semiconductor package 720, and electric resistance determined from voltage measured at the connection portion are monitored, whereby breakage of the connection portion is detected based on the value of the electric resistance. For example, a time point (the number of cycles of vertical motion of the pushers 802) when the electric resistance of a connection portion increases by 1% with respect to an initial monitoring value (initial value) of the electric resistance is judged to be a time point when the breakage of the connection portions is detected.

Such detection of breakage is performed on each of the respective connection portions at the four corners of the circuit board 710 and the semiconductor package 720, during the bending test, illustrated in FIGS. 31A and 31B, by using the bending device 800, illustrated in FIGS. 30A and 30B. In doing this, the breakage detection section 804 performs control of the electric current flowing through the connection portions, measurement of voltage of the electric current, calculation and monitoring of the electric resistance as time elapses based on the electric current and voltage, and detection (determination) of breakage of a connection portion based on the value of the electric resistance. Further, the number of cycles of vertical motion of the pushers 802, controlled by the controller 803, is supplied to the breakage detection section 804. Information (electric current, voltage, electric resistance, etc.) on the detection of breakage of a connection portion, obtained by the breakage detection section 804, is displayed on the display section 805 in association with the number of cycles of vertical motion of the pushers 802, controlled by the controller 803.

The bending test was performed on the connection portions between the circuit board 710 and the semiconductor package 720 under the above-described conditions, using the comparative sample in which the solder bumps are used and the sample 700 in which the connection members 730 are used. As a result, in the comparative sample in which the solder bumps are used, breakage of a connection portion thereof occurred at the time of a 142-nd cycle. On the other hand, in the sample 700 in which the connection members 730 are used, breakage of a connection portion thereof occurred at the time of a 926-th cycle. When the connection members 730 are used for the connection portions between the circuit board 710 and the semiconductor package 720, the fatigue life of the connection portions becomes not less than 6.5 times longer than when the solder bumps are used for the connection portions. Therefore, by using the connection members 730, it is possible to enhance the connection reliability of the connection portions between the circuit board 710 and the semiconductor package 720.

According to the above-mentioned bending test, the connection reliability of the connection portions connecting between the circuit board 710 and the semiconductor package 720 can be evaluated more appropriately in a shorter time period than by the heat cycle test.

The conditions for the bending test are not limited to the above-described example. For example, the conditions (amplitude and frequency) of the motion of the pushers 802 can be set as appropriate depending on the materials of the circuit board 710, the semiconductor package 720, and the connection members 730.

Further, in the above-described example, a criterion for determining the breakage of a connection portion between the circuit board 710 and the semiconductor package 720 is set to a time point when the electric resistance of the connection portion increases by 1% from the initial value thereof. Such a criterion for determining the breakage of a connection portion can be set as appropriate based on the materials of the circuit board 710, the semiconductor package 720, and the connection members 730, or the degree of required connection reliability.

Further, in the above-described example, the case is taken as an example, where the bending test is performed by connecting only the electrodes 711 and 721 at the four corners of the circuit board 710 and the semiconductor package 720 using the connection members 730 or the solder bumps. Instead of this, it is also possible to carry out the bending test by connecting between all the electrodes 711 of the circuit board 710 and all the electrodes 721 of the semiconductor package 720 using the connection members 730 or the like. In this case, the circuit board 710 and the semiconductor package 720 are more firmly connected to each other, so that although it takes a longer time to detect breakage of any of the connection portions, it is possible to evaluate the connection reliability of the connection portions based on an actual form of products or under conditions closer to the actual form of the products.

The evaluation of the connection reliability by the above-mentioned bending test can similarly be applied to the evaluation of the connection reliability of the connection portions between the semiconductor chip and the interposer.

According to the disclosed electronic device, it is possible to suppress breakage of the connection portions between the circuit board and the semiconductor device, and occurrence of bridges between adjacent ones of the connection portions.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present invention has(have) been described in detail, it should be understood that various changes, substitutions and alterations could be made hereto without departing from the spirit and scope of the invention.

What is claimed is:

1. An electronic device comprising:
a circuit board having a first electrode formed on a main surface thereof;
a semiconductor device disposed toward said main surface of said circuit board, said semiconductor device having a second electrode formed on a surface thereof opposed to said main surface; and
a connection member including a hollow cylindrical member and a conductive member disposed within said hollow cylindrical member, and electrically connecting between said first electrode and said second electrode.

2. The electronic device according to claim 1, wherein said hollow cylindrical member is formed by thin wire.

3. The electronic device according to claim 2, wherein said thin wire is formed into a mesh-like shape.

4. The electronic device according to claim 2, wherein said thin wire is formed into a coil-like shape.

5. The electronic device according to claim 1, wherein said hollow cylindrical member contains a metal.

6. The electronic device according to claim 1, wherein said hollow cylindrical member contains a resin.

7. The electronic device according to claim 6, wherein a surface-treated layer having wettability to said conductive member is formed on said resin.

8. The electronic device according to claim 1, wherein said hollow cylindrical member has heat resistance with respect to a melting point of said conductive member.

9. The electronic device according to claim 1, wherein said hollow cylindrical member has a concave drum shape.

10. The electronic device according to claim 1, wherein said semiconductor device includes an interposer and a semiconductor chip mounted on said interposer.

11. The electronic device according to claim 1, wherein said circuit board is an interposer, and said semiconductor device is a semiconductor chip.

12. A method of manufacturing an electronic device, comprising:
disposing a semiconductor device toward a main surface of a circuit board having a first electrode formed on the main surface, the semiconductor device having a second electrode formed on a surface thereof opposed to the main surface; and
electrically connecting the first electrode and the second electrode using a connection member including a hollow cylindrical member and a conductive member disposed within the hollow cylindrical member.

13. The method according to claim 12, wherein the semiconductor device having the connection member electrically connected in advance to the second electrodes is disposed toward the main surface of the circuit board.

14. The method according to claim 12, wherein the hollow cylindrical member is formed to have a concave drum shape.

15. Electronic equipment comprising:
a circuit board having a first electrode formed on a main surface thereof;
a semiconductor device disposed toward said main surface of said circuit board, said semiconductor device having a second electrode formed on a surface thereof opposed to said main surface; and
a connection member including a hollow cylindrical member and a conductive member disposed within said hollow cylindrical member, for electrically connecting between said first electrode and said second electrode.
